(19) United States
(12) Patent Application Publication
(10) Pub. No.: US 2014/0329379 A1
(43) Pub. Date: Nov. 6, 2014

(54) PATTERNING METHOD FOR FORMING STAIRCASE STRUCTURE AND METHOD FOR FABRICATING SEMICONDUCTOR DEVICE USING THE SAME

(71) Applicant: Samsung Electronics Co., Ltd., Suwon-si (KR)

(72) Inventors: Chul-Ho Kim, Seoul (KR); Cheolhong Kim, Yongin-si (KR); Chorong Park, Osan-si (KR); Jaehan Lee, Seoul (KR)

(73) Assignee: Samsung Electronics Co., Ltd., Suwon-si (KR)

(21) Appl. No.: 14/085,194

(22) Filed: Nov. 20, 2013

(30) Foreign Application Priority Data
May 2, 2013 (KR) 10-2013-0049502

(51) Int. Cl. H01L 21/308; H01L 21/283; H01L 21/28

(52) U.S. Cl. CPC H01L 21/3086; H01L 21/28008; H01L 21/283
USPC 438/586; 438/694

(57) ABSTRACT

A patterning method includes forming a photoresist layer on a processing layer and exposing the photoresist layer using a standing wave/defocusing exposure to produce a photoresist layer having a staircase pattern.

### CROSS-REFERENCE TO RELATED APPLICATIONS

This U.S. non-provisional patent application claims priority under 35 U.S.C. §119 of Korean Patent Application No. 10-2013-0049502, filed on May 2, 2013, the entire contents of which are hereby incorporated by reference.

### BACKGROUND

Exemplary embodiments in accordance with principles of inventive concepts relate to a semiconductor device, and more particularly, to a patterning method for forming a staircase structure and a method for fabricating a semiconductor device using the same and a semiconductor device so-fabricated.

In forming a semiconductor device with a vertical channel, a word line pad may be formed with a staircase structure for effective metal contact. As the number of word line staircases is increased, the number of staircase processes and/or process steps becomes greater. Such an increased number of processes and/or process steps may reduce yield, in particular, by increasing process defects.

### SUMMARY

Exemplary embodiments in accordance with principles of inventive concepts include a patterning method that includes forming a photoresist layer on a processing layer, performing defocusing and standing-wave exposure on the photoresist layer, developing the defocusing exposed photoresist layer to form an etching mask having a side of a staircase shape, and patterning the processing layer by an etching process using the etching mask to change the processing layer into a staircase structure.

Exemplary embodiments in accordance with principles of inventive concepts include the performing of the defocusing exposure on the photoresist layer comprises performing the defocusing exposure by adjusting a focus of light to a level higher or lower than a middle height of the photoresist layer.

Exemplary embodiments in accordance with principles of inventive concepts include a photoresist layer comprising positive resist, and the performing of the defocusing exposure on the photoresist layer comprises performing the defocusing exposure by adjusting a focus of light to a level higher than a middle height of the positive resist.

Exemplary embodiments in accordance with principles of inventive concepts include the forming of the etching mask comprises providing the positive resist with a developing solution to selectively remove an exposed portion of the positive resist, wherein an unexposed portion of the positive resist is used as the etching mask, the unexposed portion of the positive resist upwardly inclined along the side of the staircase shape and a width that tapers inward with increasing distance from the processing layer.

Exemplary embodiments in accordance with principles of inventive concepts include the photoresist layer comprising negative resist, wherein the performing of the defocusing exposure on the photoresist layer comprises performing the defocusing exposure by adjusting a focus of light to a level lower than a middle height of the negative resist.

Exemplary embodiments in accordance with principles of inventive concepts include the forming of the etching mask comprising providing the negative resist with a developing solution to selectively remove an unexposed portion of the negative resist, wherein an exposed portion of the negative resist is used as the etching mask, the exposed portion of the negative resist upwardly inclined along the side of the staircase shape and a width that tapers inward with increasing distance from the processing layer.

Exemplary embodiments in accordance with principles of inventive concepts include the forming of the photoresist layer comprising coating positive resist or negative resist on the processing layer without forming an anti-reflective layer on at least one of the processing layer and the photoresist layer.

Exemplary embodiments in accordance with principles of inventive concepts include the performing of the defocusing exposure on the photoresist layer comprises performing exposure by adjusting a focus of light to a top surface or a bottom surface of the photoresist layer without performing post exposure bake on the photoresist layer.

Exemplary embodiments in accordance with principles of inventive concepts include a processing layer comprising a single layer or a multiple layer.

Exemplary embodiments in accordance with principles of inventive concepts include the changing of the processing layer into the staircase structure comprises changing the processing layer into a pyramid structure including an outer lateral side having the staircase shape and a width that tapers inward with increasing distance from the processing layer.

Exemplary embodiments in accordance with principles of inventive concepts include the changing of the processing layer into the staircase structure comprises changing the processing layer into a recessed structure including an inner surface having the staircase shape and a width that tapers outward with increasing distance from the processing layer.

Exemplary embodiments in accordance with principles of inventive concepts include forming a multiple layer including different material layers vertically stacked alternatingly along a vertical channel standing on a substrate; forming an etching mask having an inclined side of a staircase shape on the multiple layer; and patterning the multiple layer by an etching process using the etching mask to form a side of the multilayer with a staircase structure, wherein the forming of the etching mask comprises: forming a photoresist layer on the multiple layer; performing defocusing and standing wave exposure on the photoresist layer by adjusting a focus of a light to a level higher or lower than a middle height of the photoresist layer; and developing the defocusing exposed photoresist layer.

Exemplary embodiments in accordance with principles of inventive concepts include the multilayer comprising a mold stack including insulating layers and sacrificial layers that are vertically stacked alternatingly on the substrate, wherein the mold stack is patterned through the etching process to have the staircase structure in which adjacent insulating and conductive layers are not covered by directly above adjacent insulating and conductive layers.

Exemplary embodiments in accordance with principles of inventive concepts after the forming of the side of the multiple layer with the staircase structure, further comprising: selectively removing the sacrificial layers to form recess regions between the insulating layers; and filling the recess regions with conductive layers to form a plurality of gates stacked along the vertical channel, each gate having a pad not covered by a directly above adjacent conductive layer.

Exemplary embodiments in accordance with principles of inventive concepts include multiple layer comprising a gate stack including insulating layers and conductive layers vertically stacked alternatingly on the substrate, wherein the gate stack is patterned through the etching process to have the staircase structure in which adjacent insulating and conductive layers are not covered by directly above adjacent insulating and conductive layers.

Exemplary embodiments in accordance with principles of inventive concepts include forming a photoresist layer on a processing layer; performing standing-wave exposure on the photoresist layer; focusing the standing wave exposure at a level other than at the center of the photoresist layer; developing the exposed photoresist layer to form an etching mask having a staircase shaped side; and patterning the processing layer by an etching process using the etching mask to form a staircase-structured processing layer.

Exemplary embodiments in accordance with principles of inventive concepts include standing wave exposure that includes reflecting light off a surface below the photoresist layer to constructively and destructively interfere and to thereby expose areas of the photoresist to different degrees.

Exemplary embodiments in accordance with principles of inventive concepts include the exposure is focused at or near the bottom of the photoresist layer to form a region of exposed photoresist in a staircase pattern that inclines outwardly toward the top of the photoresist layer.

Exemplary embodiments in accordance with principles of inventive concepts include the exposure focused at or near the top of the photoresist layer to form a region of exposed photoresist in a staircase pattern that inclines inwardly toward the top of the photoresist layer.

Exemplary embodiments in accordance with principles of inventive concepts include the unexposed portion of the resist used as an etch mask.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1A is a plan view illustrating a semiconductor device according to an exemplary embodiment in accordance with principles of inventive concepts exemplary embodiment in accordance with principles of inventive concepts;

FIG. 1B is a plan view illustrating a semiconductor device according to another exemplary embodiment in accordance with principles of inventive concepts exemplary embodiment in accordance with principles of inventive concepts;

FIGS. 2A to 6A are sectional views taken along a line A1-A2 of FIG. 1A and illustrate a method for fabricating a semiconductor device according to an exemplary embodiment in accordance with principles of inventive concepts exemplary embodiment in accordance with principles of inventive concepts;

FIGS. 2B to 6B are sectional views taken along a line B1-B2 of FIG. 1A and illustrate a method for fabricating a semiconductor device according to an exemplary embodiment in accordance with principles of inventive concepts exemplary embodiment in accordance with principles of inventive concepts;

FIGS. 7A and 8A are sectional views illustrating modifications of FIG. 6A;

FIGS. 7B and 8B are sectional views illustrating modifications of FIG. 6B;

FIGS. 9A to 12A are sectional views taken along a line C1-C2 of FIG. 1B and illustrate a method for fabricating a semiconductor device according to another exemplary embodiment in accordance with principles of inventive concepts exemplary embodiment in accordance with principles of inventive concepts;

FIGS. 9B to 12B are sectional views taken along a line D1-D2 of FIG. 1B and illustrate a method for fabricating a semiconductor device according to another exemplary embodiment in accordance with principles of inventive concepts exemplary embodiment in accordance with principles of inventive concepts;

FIG. 13A is a sectional view illustrating a photo process in relation to a patterning method for forming a staircase structure according to an exemplary embodiment in accordance with principles of inventive concepts exemplary embodiment in accordance with principles of inventive concepts;

FIG. 13B is a graph illustrating standing wave in relation to a patterning method for forming a staircase structure according to an exemplary embodiment in accordance with principles of inventive concepts exemplary embodiment in accordance with principles of inventive concepts;

FIGS. 14A to 14C are sectional views illustrating an etching mask in relation to a patterning method for forming a staircase structure according to an exemplary embodiment in accordance with principles of inventive concepts exemplary embodiment in accordance with principles of inventive concepts;

FIGS. 15A to 15C are sectional views illustrating an etching mask in relation to a patterning method for forming a staircase structure according to another exemplary embodiment in accordance with principles of inventive concepts;

FIGS. 16A and 16F are sectional views corresponding to FIG. 3B and illustrate a method for patterning a staircase structure according to an exemplary embodiment in accordance with principles of inventive concepts;

FIGS. 17A and 17B are sectional views corresponding to FIG. 3B and illustrate a patterning method for forming a staircase structure according to another exemplary embodiment in accordance with principles of inventive concepts;

FIGS. 18A to 18E are sectional views illustrating a patterning method for forming a staircase structure according to another exemplary embodiment in accordance with principles of inventive concepts;

FIG. 19A is a block diagram illustrating a memory card including a semiconductor device according to embodiments of the present invention; and

FIG. 19B is a block diagram illustrating an information processing system including a semiconductor device applied according to embodiments of the present invention.

### DESCRIPTION

Various exemplary embodiments will be described more fully hereinafter with reference to the accompanying drawings, in which exemplary embodiments are shown. Exemplary embodiments may, however, be embodied in many different forms and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, for example. may be used herein to describe various elements, components, regions, layers and/or sections, these elements, components, regions, layers and/or sections should not be limited by these terms. These terms are only used to distinguish one element, component, region, layer or section from another region, layer or section. In this manner, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. In this manner, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. In this manner, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In this manner, the regions illustrated in the figures are schematic in nature and their shapes are not intended to illustrate the actual shape of a region of a device and are not intended to limit the scope of exemplary embodiments.

Unless otherwise defined, all tennis (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments in accordance with principles of inventive concepts will be explained in detail with reference to the accompanying drawings.

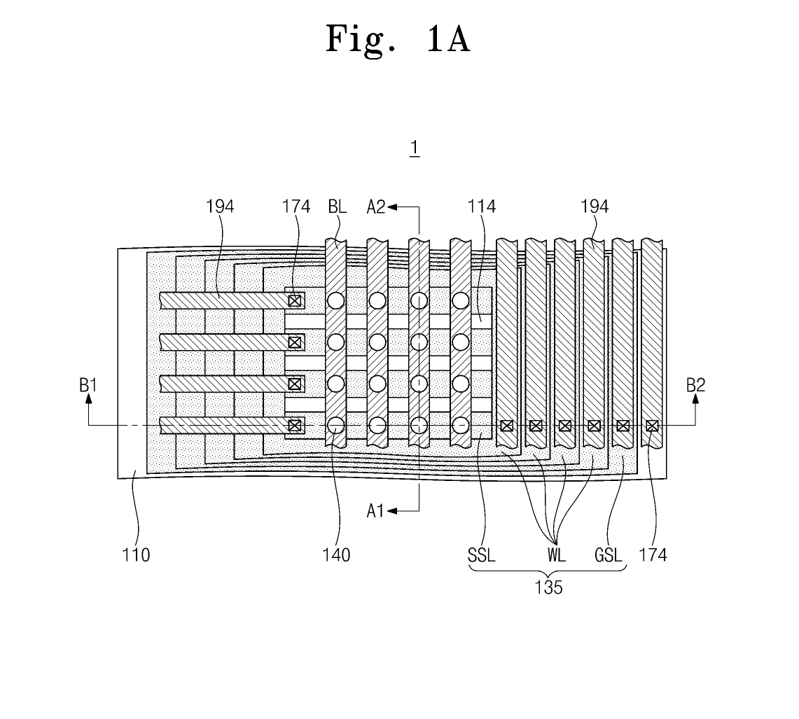

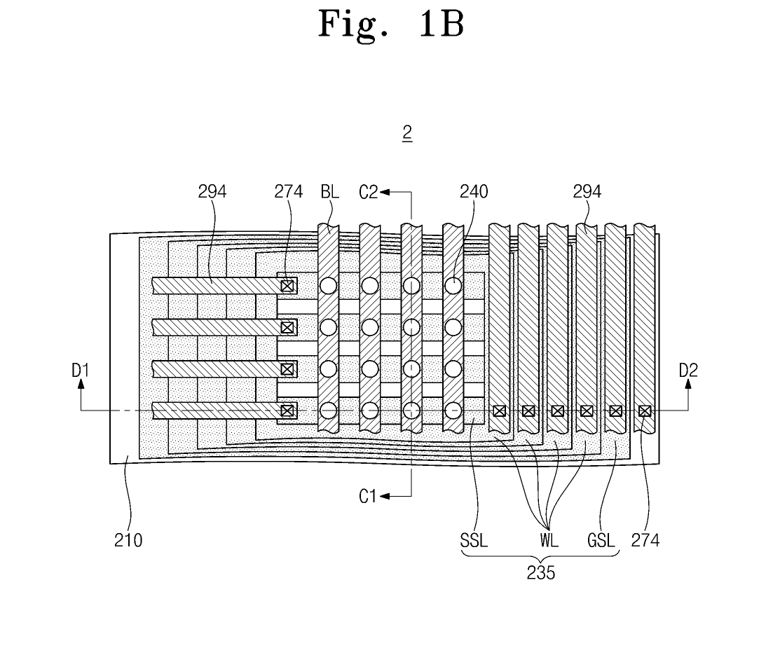

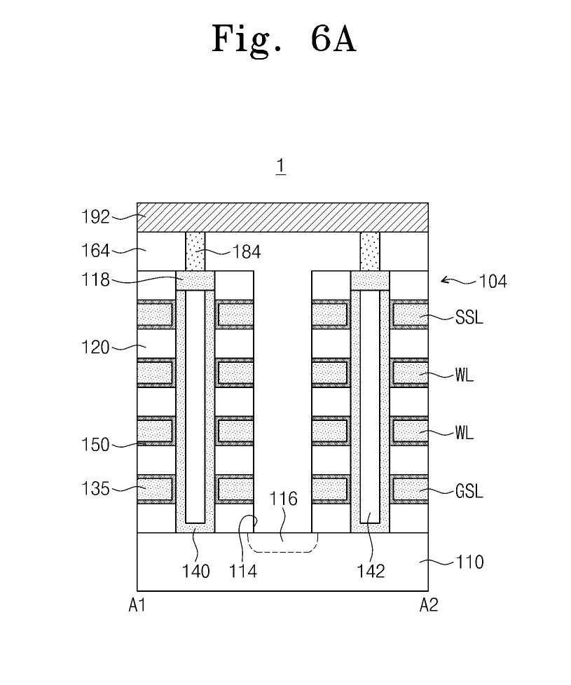

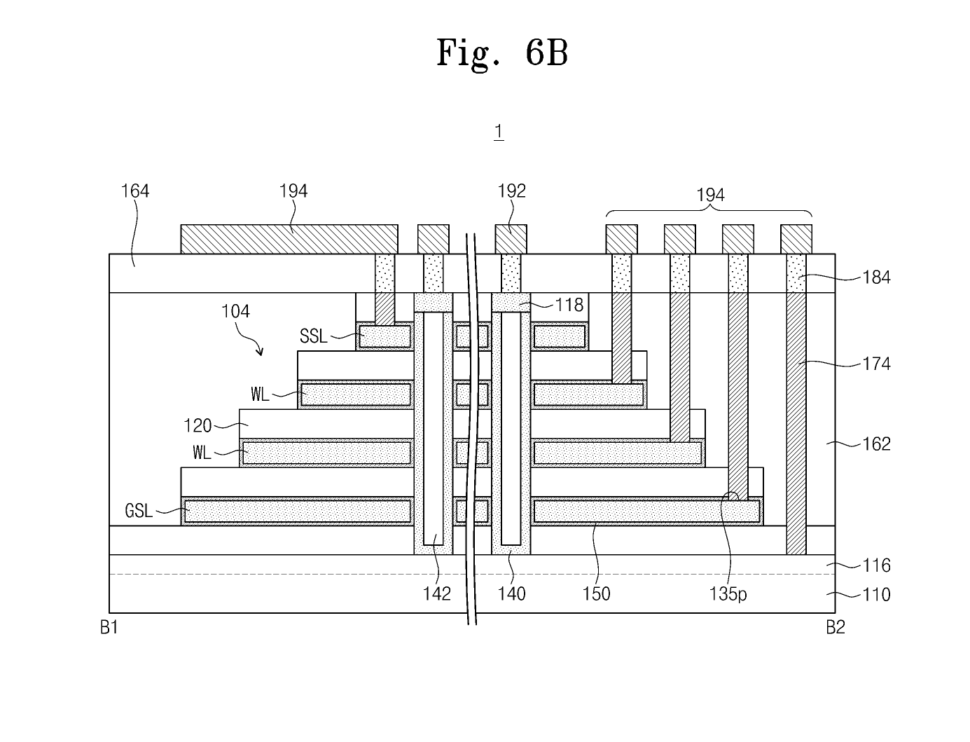

FIG. 1A is a plan view illustrating a semiconductor device according to an exemplary embodiment in accordance with principles of inventive concepts. Semiconductor device 1 may include a plurality of vertical channels 140 vertically standing on a substrate 110, a plurality of gates 135 stacked along the vertical channels 140, and bit lines BL electrically connected to the vertical channels 140. The semiconductor device 1 may be a semiconductor memory device, for example, a NAND flash memory device or a variable-resistance memory device, that further includes a plurality of memory layers 150 between the vertical channel 140 and the gates 135 as shown in FIG. 6B.

The gates 135 may constitute a ground selection line GSL adjacent to the substrate 110, a string selection line SSL adjacent to the bit line BL, and word lines WL between the selection lines GSL and SSL, for example. The gates 135 and the substrate 110 may be electrically connected to metal lines 194 via first contact plugs 174. Each of the vertical channels 140 may have a bottom electrically connected to the substrate 110 and a top electrically connected to the bit line BL via a second contact plug 184 of FIG. 6B.

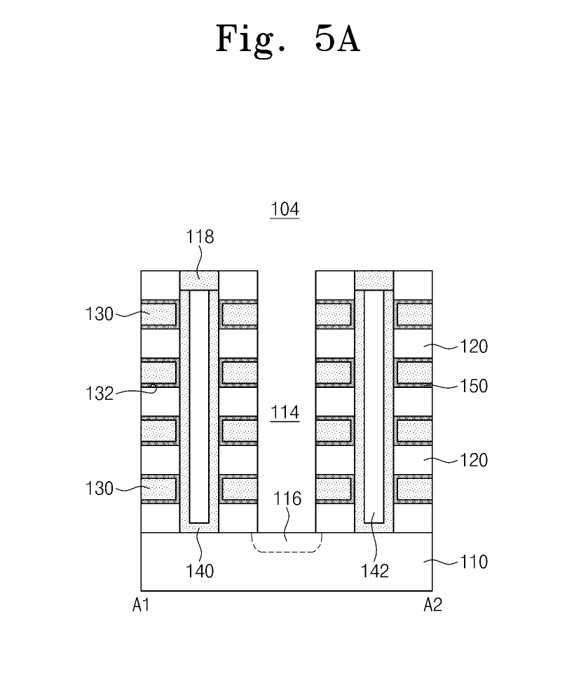

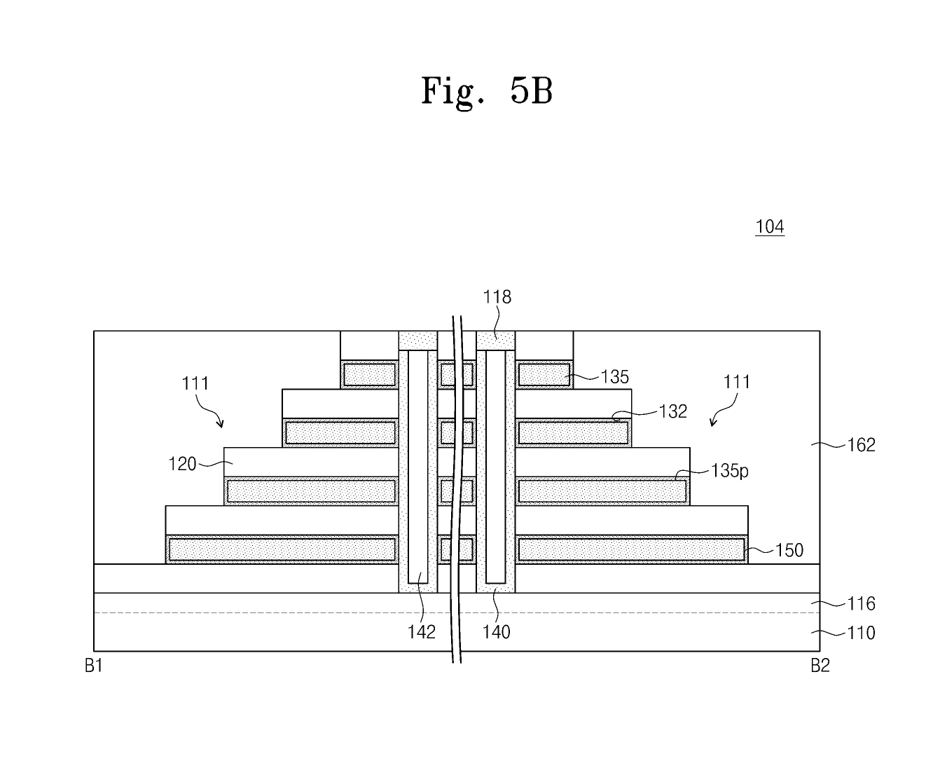

In exemplary embodiments in accordance with principles of inventive concepts, as shown in FIG. 5B, the gates 135 may be stacked in a pyramid shape, so that two, or four, sides may form a staircase structure 111. Gates 135 may have pads 135p where the first contact plugs 174 contact thereto. The string selection line SSL may have a line shape extending in a B1-B2 direction intersecting an A1-A2 direction that is an extension of the direction of the bit line BL. The word lines WL and the ground selection line GSL may have a plate shape having word line cuts 114 that extend in the B1-B2 direction and expose the substrate 110.

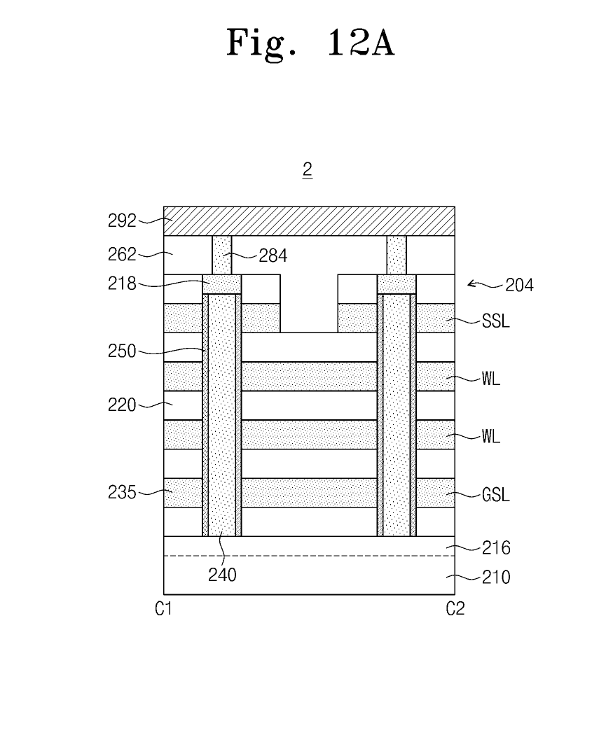

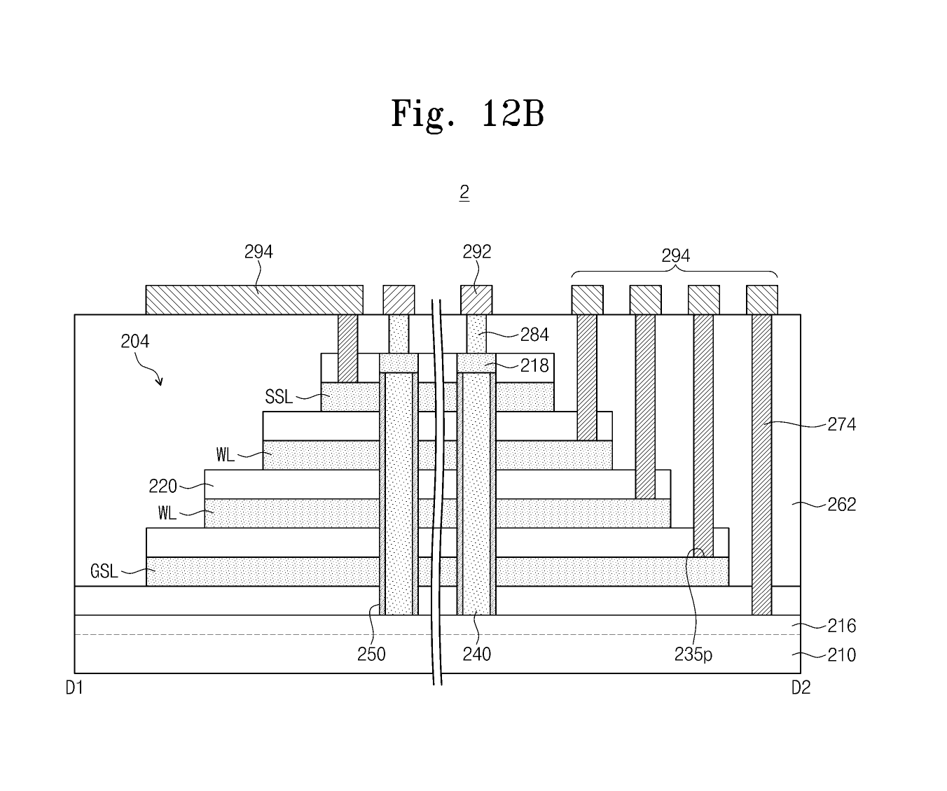

FIG. 1B is a plan view illustrating a semiconductor device according to another exemplary embodiment in accordance with principles of inventive concepts. Semiconductor device 2 may include a plurality of vertical channels 240 vertically extending on a substrate 210, a plurality of gates 235 stacked along the vertical channels 240, and bit lines BL electrically connected to the vertical channels 240. The semiconductor device 2 may be a semiconductor memory device, for example, such as a NAND flash memory device or a variable-resistance memory device, that further includes a plurality of memory layers 250 extending along the vertical channel 240 as shown in FIG. 12B.

The gates 235 may constitute a ground selection line GSL adjacent to the substrate 210, a string selection line SSL adjacent to the bit line BL, and word lines WL between the selection lines GSL and SSL. The gates 235 and the substrate 210 may be electrically connected to metal lines 294 via first contact plugs 274. Each of the vertical channels 240 may have a bottom electrically connected to the substrate 210 and a top electrically connected to the bit line BL via a second contact plug 284 of FIG. 12B, for example.

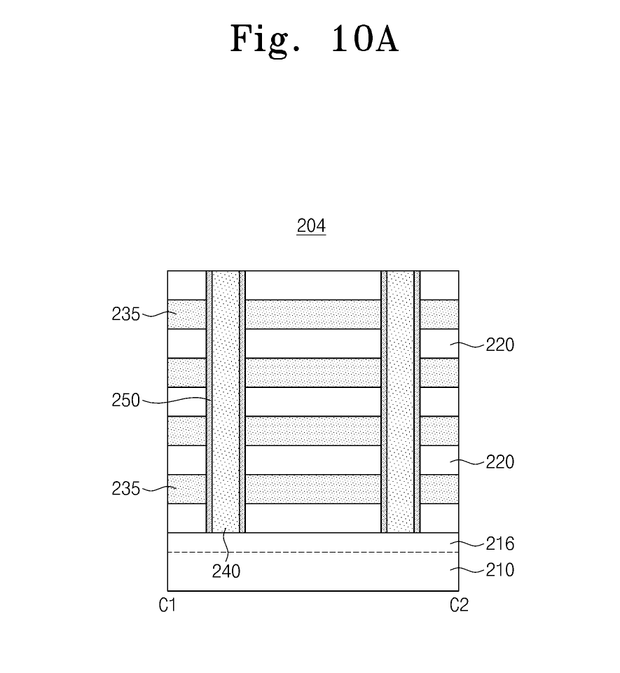

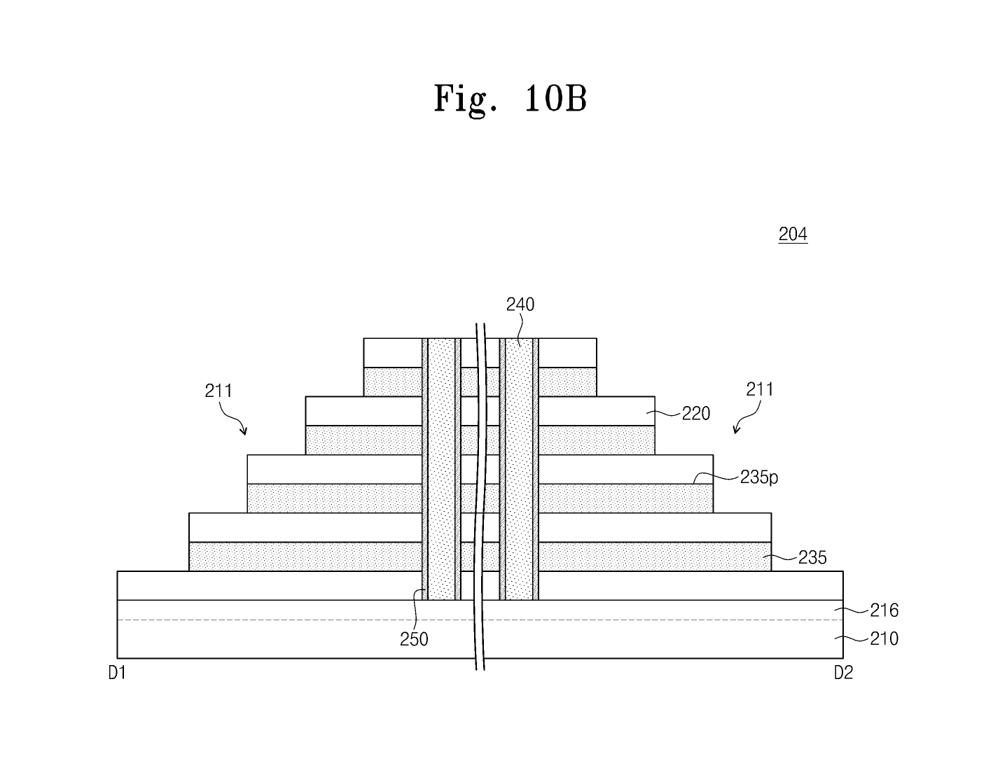

In exemplary embodiments in accordance with principles of inventive concepts, as shown in FIG. 10B, the gates 235 may be stacked in a pyramid shape, so that two, or four, sides may form a staircase structure 211. Accordingly, the gates 235 may have pads 235p where the first contact plugs 274 contact thereto. The string selection line SSL may have a line shape extending in a D1-D2 direction intersecting a C1-C2 direction that is an extension of the direction of the bit line BL. The word lines WL and the ground selection line GSL may have a plate shape, for example.

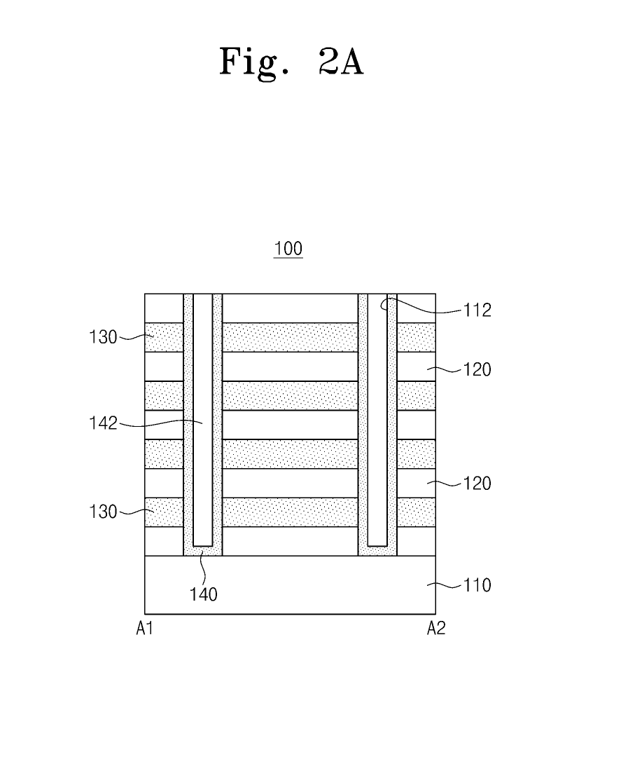

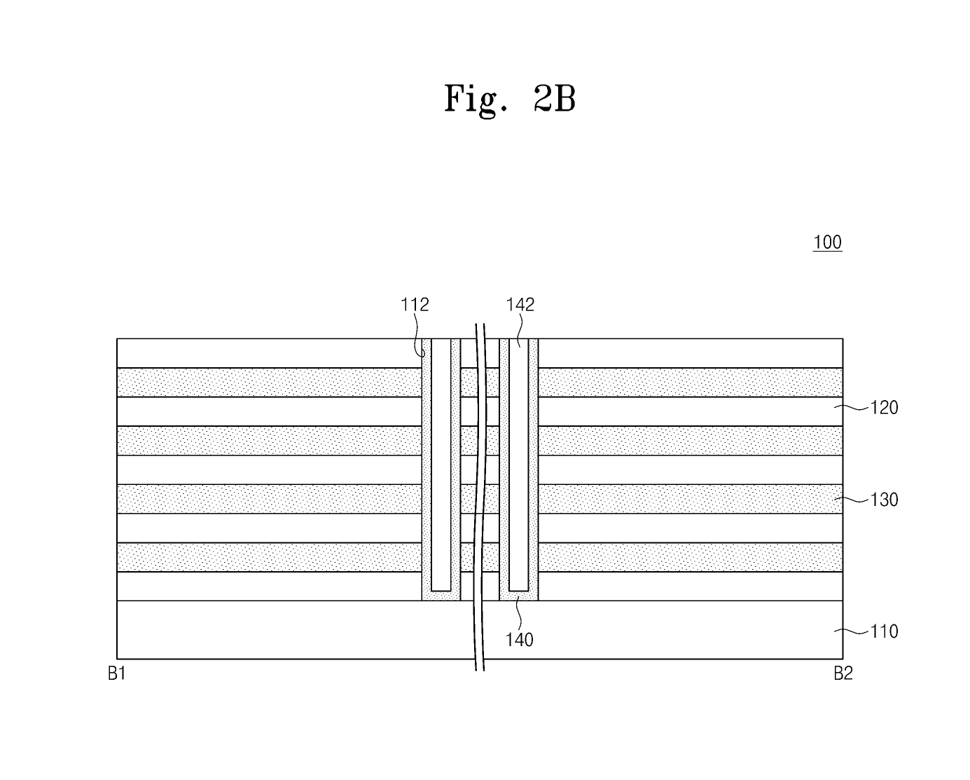

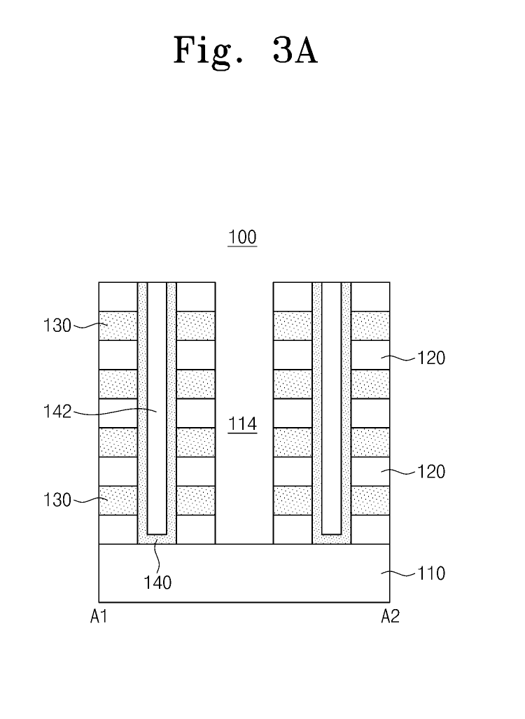

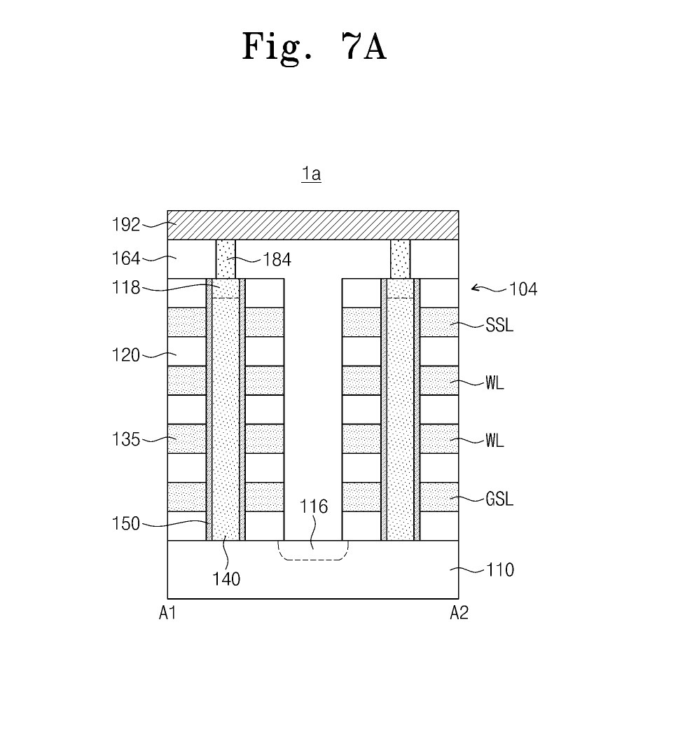

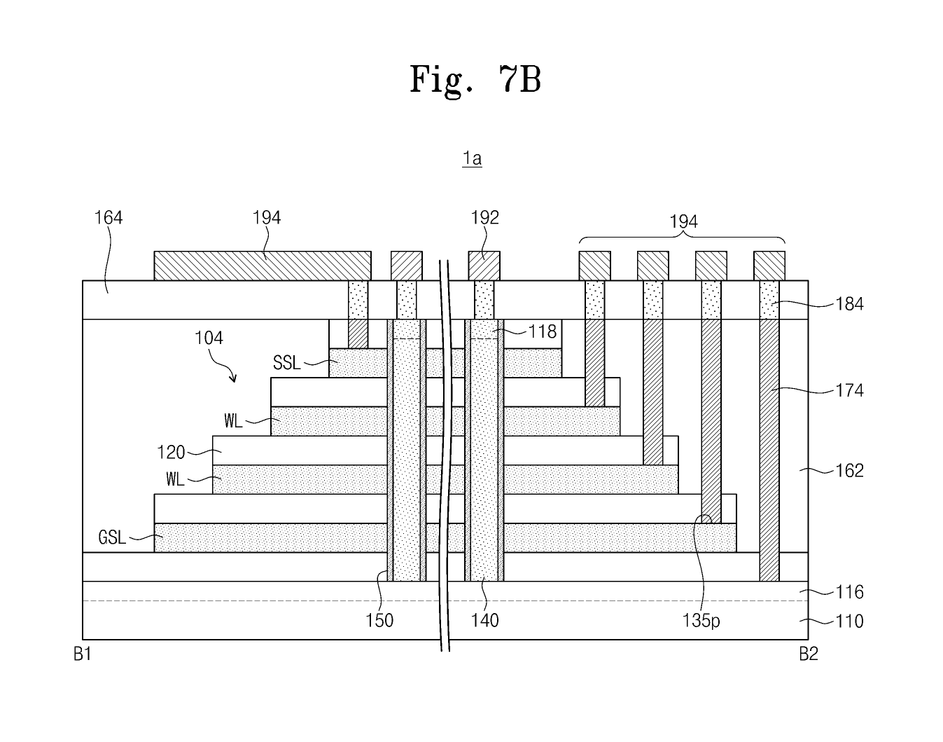

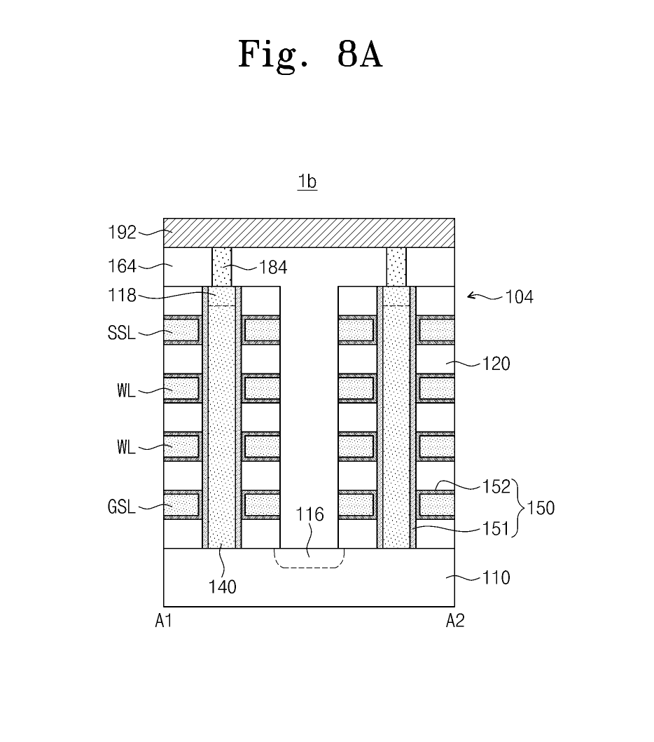

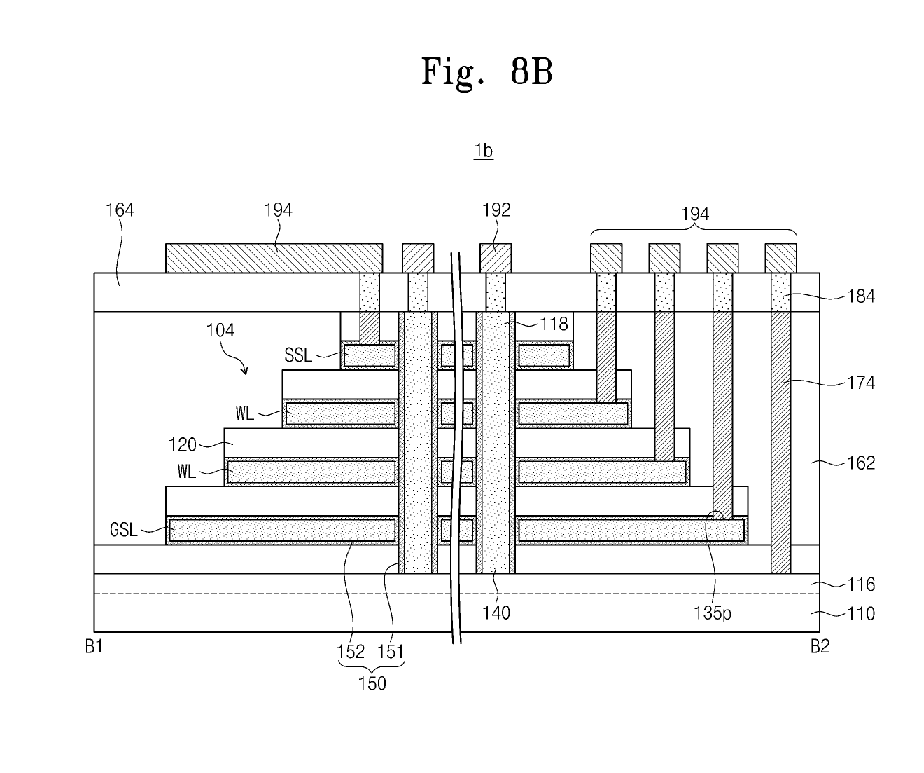

FIGS. 2A to 6A are sectional views taken along a line A1-A2 of FIG. 1A that illustrate a method for fabricating a semiconductor device according to an exemplary embodiment in accordance with principles of inventive concepts. FIGS. 2B to 6B are sectional views taken along a line B1-B2 of FIG. 1A that illustrate a method for fabricating a semiconductor device according to an exemplary embodiment in accordance with principles of inventive concepts. FIGS. 7A and 8A are sectional views illustrating modifications of FIG. 6A. FIGS. 7B and 8B are sectional views illustrating modifications of FIG. 6B.

Referring to FIGS. 2A and 2B, a mold stack 100 may be formed on a substrate 110, and a vertical channel 140 may be formed to penetrate the mold stack 100 to be electrically connected to the substrate 110. The substrate 110 may be a semiconductor substrate such as a single-crystalline silicon wafer doped with a first conductive type (for example, a P type), for example. The mold stack 100 may be formed by alternately stacking a plurality of mold insulating layers 120 and a plurality of sacrificial layers 130. The mold insulating layers 120 and the mold sacrificial layers 130 may include insulators having different etch selectivity. For example, the mold insulating layers 120 may include a silicon oxide layer and the mold sacrificial layers 130 may include a silicon nitride layer.

A vertical hole 112 may be formed to penetrate the mold stack 100 so as to expose the substrate 110, and a vertical channel 140 may be formed to fill, at least partially, the vertical hole 112. The vertical hole 112 may have a pillar shape that exposes the substrate 110 by etching (for example, dry etching) the mold stack 100. The vertical channel 140 may be formed of the same or similar material to the substrate 110, for example, silicon. For example, the vertical channel 140 may have a cylindrical shape having a closed bottom contacting the substrate 110 and an opened top opposite the closed bottom. The vertical hole 112, which, in exemplary embodiments, is not completely filled by the vertical channel 140, may be filled with an inner insulating layer 142. In other exemplary embodiments in accordance with principles of inventive concepts, the vertical channel 140 may be formed in a pillar shape that completely fills the vertical hole 112.

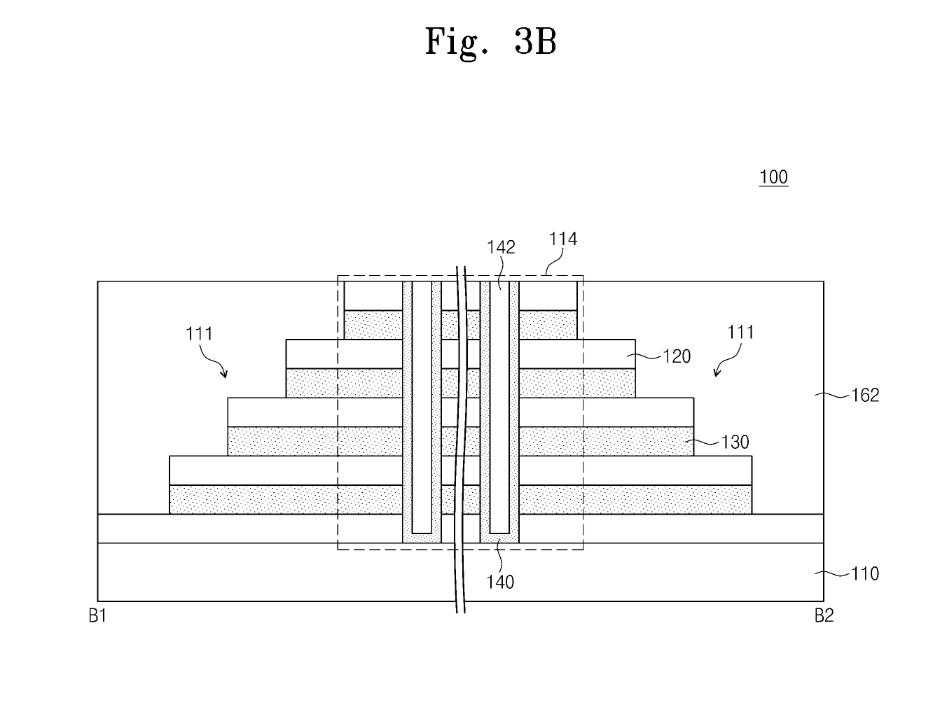

Referring to FIGS. 3A and 3B, the mold stack 100 may be patterned to form a word line cut 114 between adjacent vertical channels 140. For example, the mold insulating layers 120 and the mold sacrificial layers 130 between adjacent vertical channels 140 may be selectively etched by an etching process (for example, dry etch) to form the word line cut 114 that exposes the substrate 110 or a lowermost one of the mold insulating layers 120. The word line cut 114 may have a trench shape extending in the B1 to B2 direction of FIG. 1A.

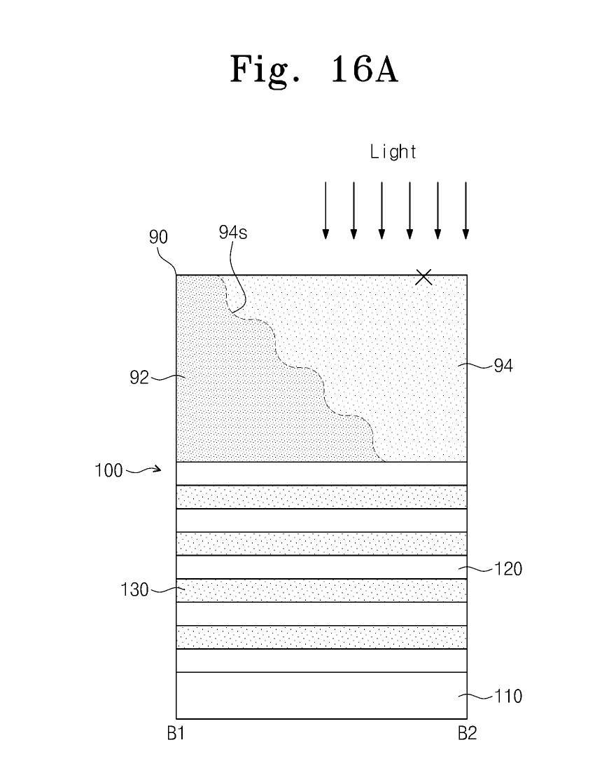

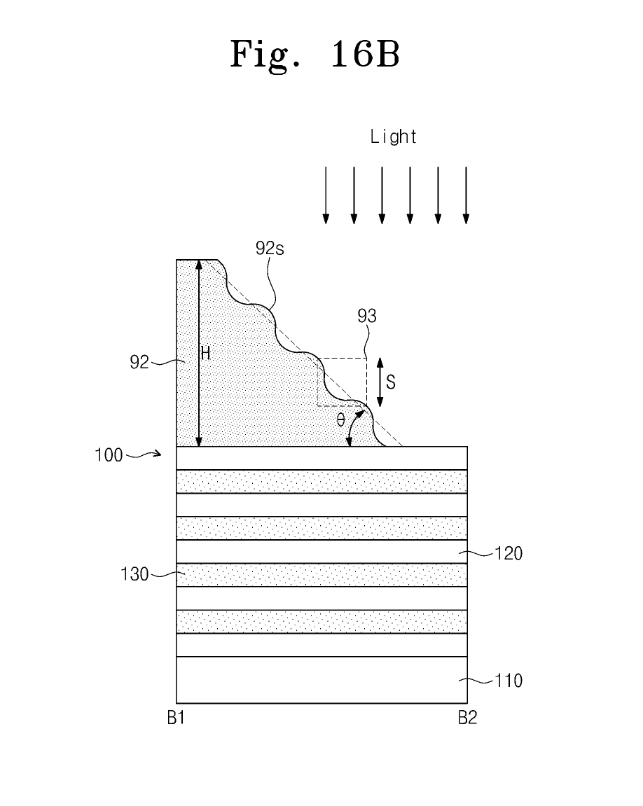

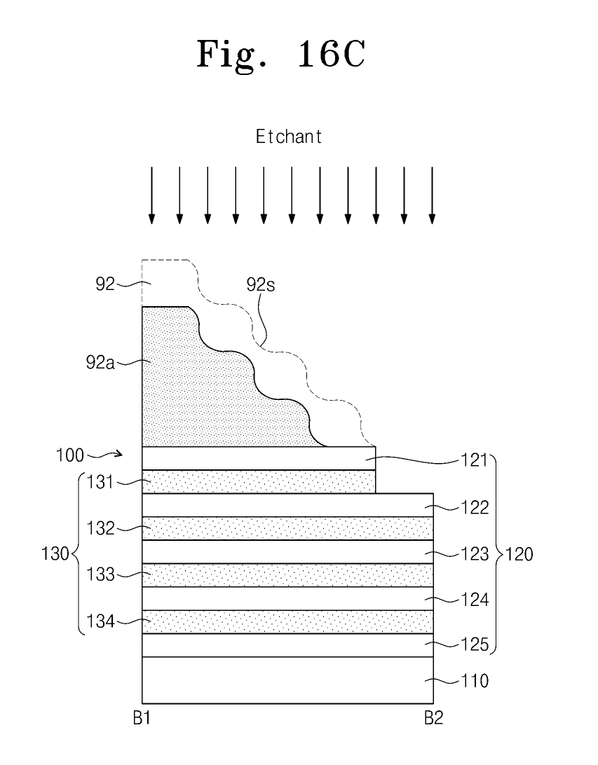

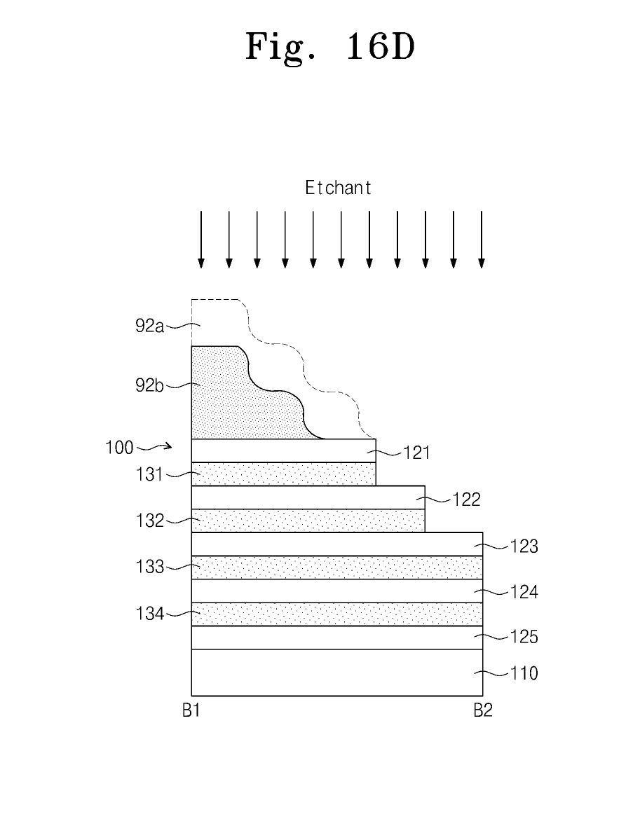

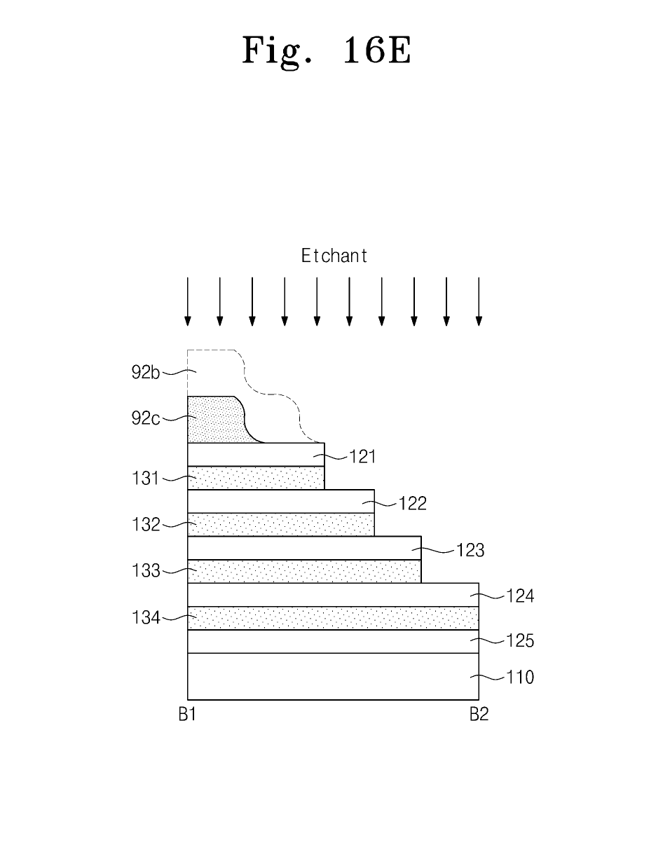

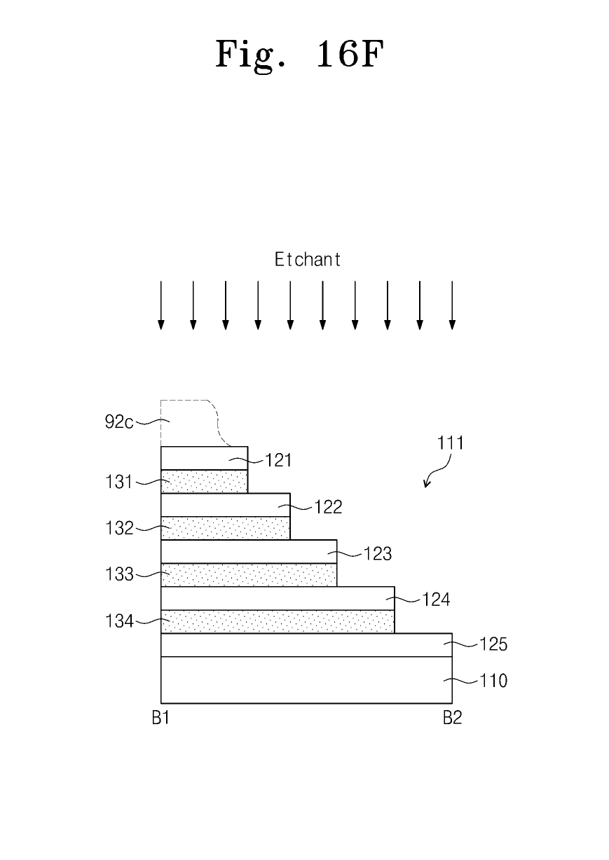

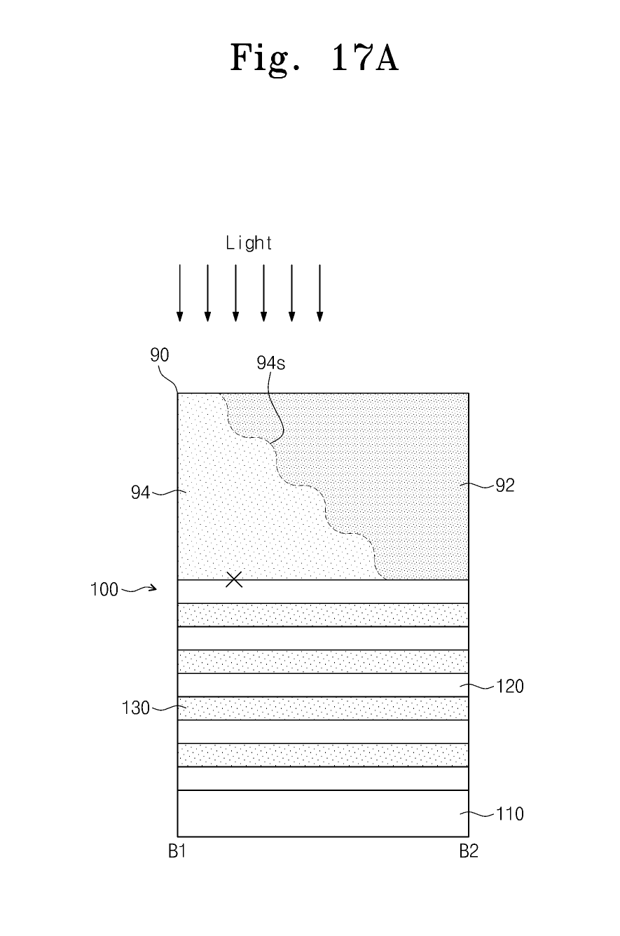

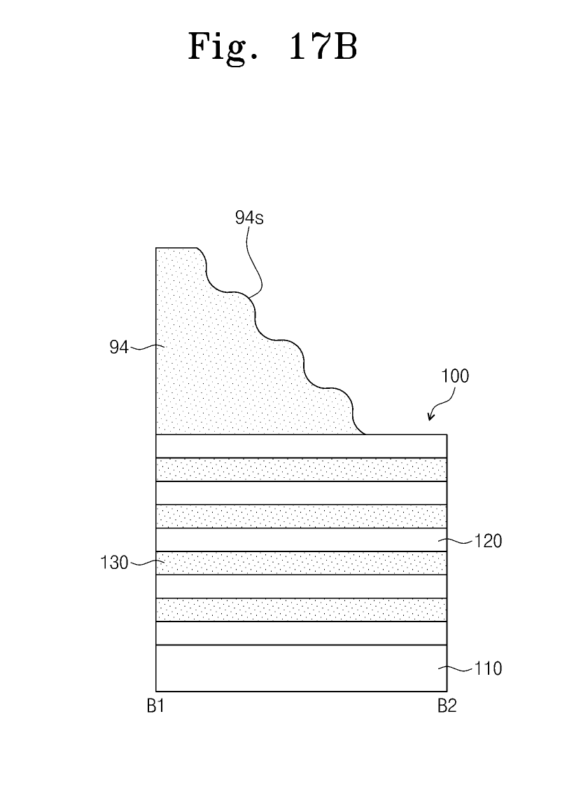

Before or after the forming of the word line cut 114, there may be formed a staircase structure 111 in which the B1-B2 direction length of the mold insulating layers 120 and/or the mold sacrificial layers 130 gradually becomes shorter with increasing distance from the substrate 110. An exemplary staircase process in accordance with principles of inventive concepts for forming the staircase structure 111 will be described later with reference to FIGS. 16A to 16F or FIGS. 17A and 17B. After the forming of the staircase structure 111, insulator (for example, silicon oxide) may be deposited to form a capping insulating layer 162 to cover the staircase structure 111. The word line cut 114 may be formed after or before the forming of the capping insulating layer 162.

The B1-B2 direction length of the word line cut 114 may be identical to or greater than the B1-B2 direction length of an uppermost mold insulating layer 120 and/or an uppermost mold sacrificial layer 130, and may be less than the B1-B2 direction length of the mold insulating layer 120 and/or mold insulating layer 130 directly below the uppermost mold insulating layer 120 and/or the uppermost mold sacrificial layer 130. Accordingly, the uppermost mold insulating layer 120 and the uppermost mold sacrificial layer 130 may be separated in the A1-A2 direction of FIG. 1A by the word line cut 114, and the remaining mold insulating layers 120 and mold sacrificial layers 130 may have a plate shape including the word line cut 114.

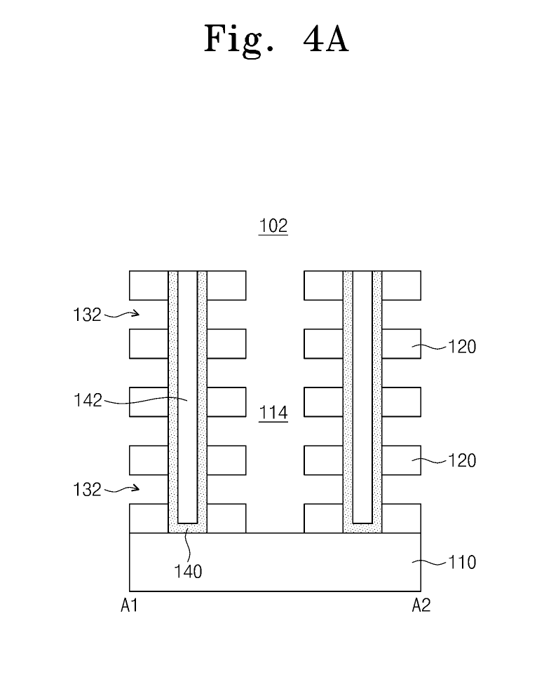

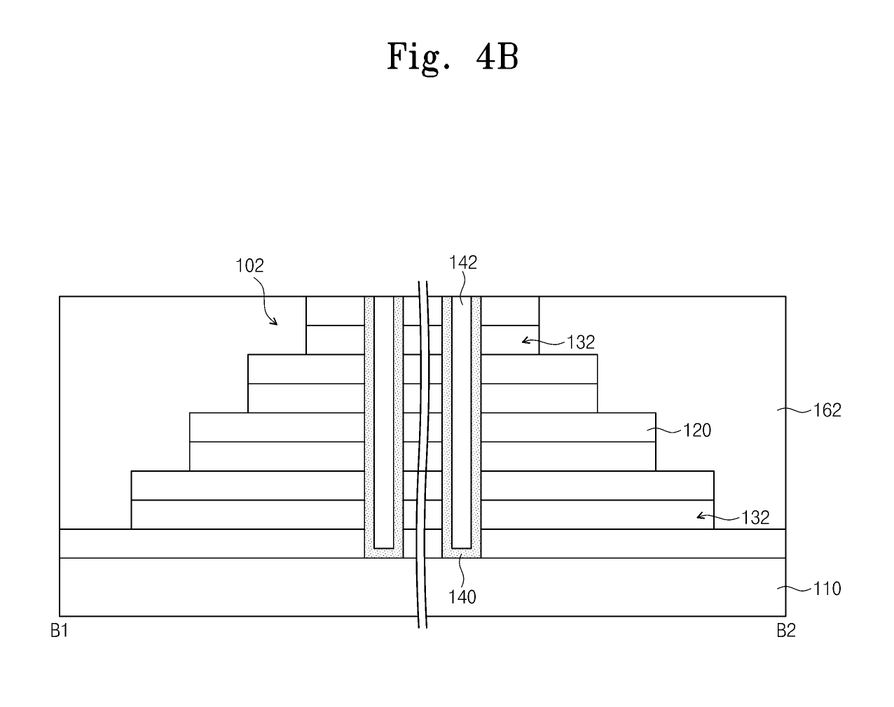

Referring to FIGS. 4A and 4B, a mold wing 102 may be formed by selectively removing the mold sacrificial layers 130. For example, when the mold sacrificial layers 130 are silicon nitride layers, an etchant such as H₃PO₄ may be provided through the word line cut 114 to selectively remove the mold sacrificial layers 130 such that recess regions 132 may be formed. The mold insulating layers 120 may be vertically spaced apart from each other along the vertical channel 140 through the wet etching, thereby forming the mold wing 102 on the substrate 110.

Referring to FIGS. 5A and 5B, a gate stack 104 may be formed by filling the recess regions 132 with memory layers 150 and gates 135. Gate 135 may be surrounded by memory layer 150, for example. The memory layer 150 may include an insulator for trapping charges or a variable resistor having variable resistance. For example, the memory layer 150 may include a trap insulating layer sandwiched between a tunnel insulating layer adjacent to the mold insulating layer 120 and a blocking insulating layer adjacent to the gate 135. In other exemplary embodiments in accordance with principles of inventive concepts, the memory layer 150 may include a transition metal oxide layer. The gate 135 may include a conductor such as tungsten, a metal nitride layer, or metal silicide layer.

A common source 116 of a second conductive type (for example, an N type) may be formed by injecting impurities into the substrate 110 exposed through the word line cut 114. The common source 116 may have a line shape extending in the B1-B2 direction of the common source 116. After a top portion of the vertical channel 140 is recessed, a second conductive drain 118 may be formed by filling the recessed top end of the vertical channel 140 or by injecting impurities into the top portion of the vertical channel 140. In other exemplary embodiments in accordance with principles of inventive concepts, before forming the word line cut 114, as shown in FIGS. 2A and 2B, after the forming of the vertical channel 140, after the top portion of the vertical channel 140 is recessed, the drain 118 may be formed by filling the recessed top portion of the vertical channel 140 with a semiconductor layer or by injecting impurities into the top portion of the vertical channel 140.

In exemplary embodiments in accordance with principles of inventive concepts, the gates 135 may have a staircase structure 111 formed by filling the recess regions 132 that are formed by removing the mold sacrificial layers 130 patterned with the staircase structure 111. That is, the gates 135 may have the staircase structure 111 in which the B1-B2 direction length becomes shorter gradually with increasing distance from the substrate 110. Accordingly, the gate 135 may have a pad 135p which is not covered by the directly above gate 135.

Referring to FIGS. 6A and 6B, bit lines 192 may be formed to be electrically connected to the vertical channels 140, and metal lines 194 may be formed to be electrically connected to the gates 135 and the substrate 110. For example, an interlayer insulating layer 164 may be formed on the substrate 110 to cover the gate stack 104 and fill the word line cut 114, and first contact plugs 174 may be formed to penetrate the interlayer insulating layers 164, the capping insulating layer 162, and the mold insulating layer 120 to be electrically connected to the gates 135 and the substrate 110. Additionally, second contact plugs 184 may be formed to penetrate the interlayer insulating layer 164 to be electrically connected to the drains 118 and the first contact plugs 174, and the bit lines 192 and the metal lines 194 may be formed on the interlayer insulating layer 164 to be electrically connected to the second contact plugs 184. In other exemplary embodiments in accordance with principles of inventive concepts, the forming of the interlayer insulating layer 164 and the second contact plugs 184 may be skipped.

In exemplary embodiments in accordance with principles of inventive concepts, the uppermost layer gate 135 may configure the string selection line SSL, the lowermost gate 135 may configure the ground selection line GSL, and a plurality of middle gates 135 may configure the word lines WL. The first contact plugs 174 may contact the pads 135p of the gates 135 and the common source 116, for example.

A semiconductor device 1 in accordance with principles of inventive concepts may be manufactured through the series of processes. For example, when the memory layer 150 includes a tunnel insulating layer, a trap insulating layer, and a blocking insulating layer, the semiconductor device 1 may be a NAND FLASH memory device. In other exemplary embodiments in accordance with principles of inventive concepts, when the memory layer 150 includes a transition metal oxide layer, the semiconductor device 1 may be a variable resistance memory device (for example, PRAM).

In accordance with principles of inventive concepts, the memory layer 150 and the vertical channel 140 may have various shapes. For example, as shown in FIGS. 7A and 7B, a semiconductor device 1a may include memory layer 150 vertically extending along the vertical channel 140 of a pillar shape. The drain 118 may be formed by injecting impurities into the top portion of the vertical channel 140. In other exemplary embodiments in accordance with principles of inventive concepts, as shown in FIGS. 8A and 8B, a semiconductor device 1b may include a first memory layer 151 vertically extending along the vertical channel 140 of a pillar shape and a second memory layer 152 surrounding the gate 135.

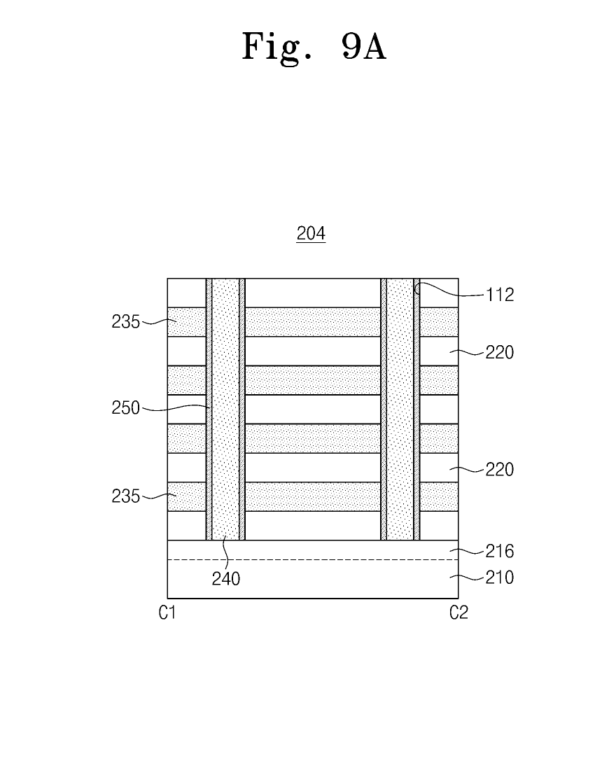

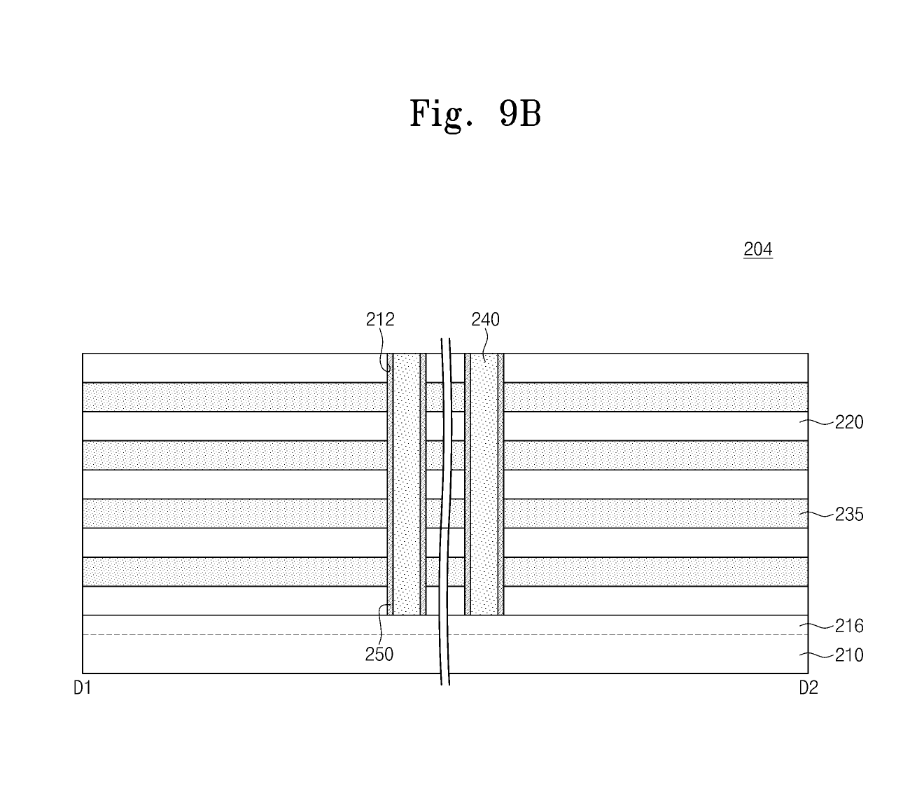

FIGS. 9A to 12A are sectional views taken along a line C1-C2 of FIG. 1B that illustrate a method for fabricating a semiconductor device according to another exemplary embodiment in accordance with principles of inventive concepts. FIGS. 9B to 12B are sectional views taken along a line D1-D2 of FIG. 1B that illustrate a method for fabricating a semiconductor device according to another exemplary embodiment in accordance with principles of inventive concepts.

Referring to FIGS. 9A and 9B, a gate stack 204 may be formed on a substrate 210, and a memory layer 250 and a vertical channel 240 may be formed to penetrate the gate stack 204. For example, the gate stack 204 may be formed by alternately stacking mold insulating layers 220 and gates 235. The mold insulating layers 220 may include an insulator such as a silicon oxide layer or a silicon nitride layer, and the gates 235 may include a conductor such as silicon metal. The gate stack 204 may be etched by an etching process (for example, a dry etch) to form a vertical hole 212 penetrating the gate stack 204, the memory layer 250 may be formed to vertically extend along an inner wall of the vertical hole 212, and the vertical channel 240 may be formed to be surrounded by the memory layer 250. The memory layer 250 may include a tunnel insulating layer, a trap insulating layer, and a blocking insulating layer, or may include a transition metal oxide layer. The vertical channel 240 may have a pillar shape. In other exemplary embodiments in accordance with principles of inventive concepts, the vertical channel 240 may have a cylindrical shape such as illustrated in FIG. 2A. The substrate 210 may be a semiconductor substrate such as a silicon wafer of a first conductive type (for example, a P type). Before the forming of the gate stack 204, impurities may be injected to the substrate 210 to form a common source 216 of a second conductive type (for example, an N type). The vertical channel 240 may be electrically connected to the common source 216.

Referring to FIGS. 10A and 10B, the gate stack 204 may be patterned to form a staircase structure 211. As mold insulating layers 220 and/or gates 235 are farther away from the substrate 210, the D1 to D2 direction length may sequentially shorten. The gate 235 may have a pad 235p that is not covered by the directly above gate 235. A staircase process for forming the staircase structure 211 will be described later in the discussion related to FIGS. 16A to 16F or FIGS. 17A and 17B.

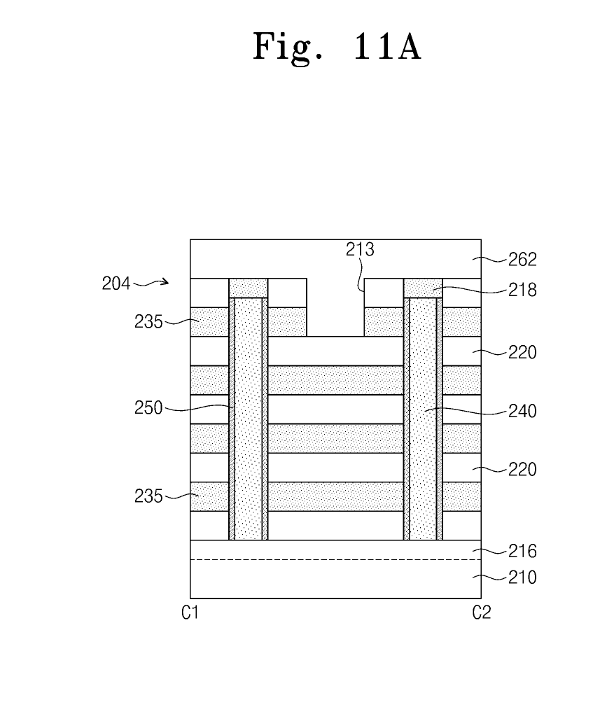

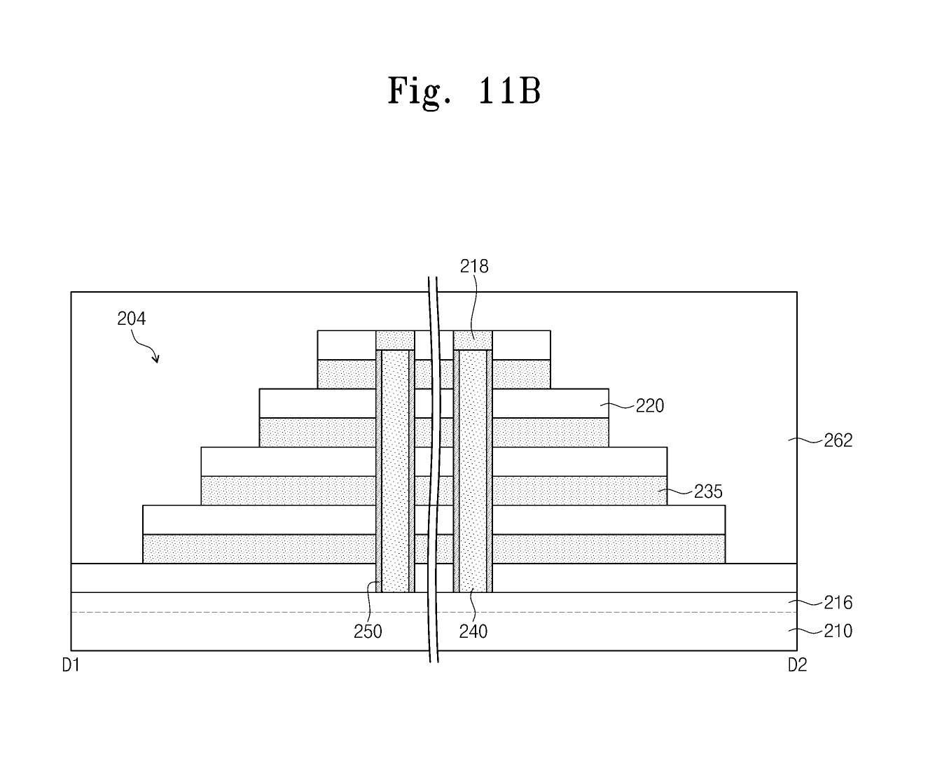

Referring to FIGS. 11A and 11B, a slit 213 may be formed by patterning an uppermost layer mold insulating layer 220 and an uppermost gate 230, and a capping insulating layer 262 may be formed to cover the gate stack 204 and fill the slit 213. Due to the formation of the slit 213, the uppermost gate 235 of a plate shape may be altered into a plurality of line shapes separated in the C1-C2 direction. The capping insulating layer 262 may be formed by depositing insulator such as a silicon oxide layer, for example. A drain 218 may be formed at a top portion of the vertical channel 240. For example, before or after forming the slit 213, the drain 218 of a second type may be formed by recessing the top portion of the vertical channel 240 and then forming a semiconductor layer filling the recessed top portion of the vertical channel 240, or by injecting impurities into the top portion of the vertical channel 240. That is, the formation of the drain 218 may be performed at the step of FIGS. 11A and 11B, or at the step of FIGS. 9A and 9B, for example. In other exemplary embodiments in accordance with principles of inventive concepts, before the forming of the staircase structure 211, for example, after forming the vertical channel 240, the drain 218 may be formed by recessing the top portion of the vertical channel 240 and then forming a semiconductor layer filling the recessed top portion of the vertical channel 240, or by injecting impurities into the top portion of the vertical channel 240, as shown in FIGS. 9A and 9B.

Referring to FIGS. 12A and 12B, bit lines 292 may be electrically connected to the vertical channels 240, and metal lines 294 may be electrically connected to the gates 235 and the substrate 210. For example, first contact plugs 274 may penetrate the capping insulating layer 262 and the mold insulating layer 220 may be connected to the gates 235 and the substrate 210, and second contact plugs 284 may penetrate the capping insulating layer 262 to be electrically connected to the drains 218. Then, the bit lines 292 may be formed on the capping insulating layer 262 to be electrically connected to the second contact plugs 284, and the metal lines 194 may be formed to be electrically connected to the first contact plugs 274. The first contact plugs 274 and the second contact plugs 284 may be sequentially or simultaneously formed.

In exemplary embodiments in accordance with principles of inventive concepts, the uppermost gate 235 may configure the string selection line SSL, the lowermost gate 235 may configure the ground selection line, and a plurality of middle gates 235 may configure the word lines WL. The first contact plugs 274 may contact the pads 235p of the gates 235 and the common source 216, and the second contact plugs 284 may contact the drain 218.

A semiconductor device 2 may be manufactured through the series of processes in accordance with principles of inventive concepts. For example, when the memory layer 250 includes a tunnel insulating layer, a trap insulating layer, and a blocking insulating layer, the semiconductor device 2 may be a NAND FLASH memory device. In other exemplary embodiments in accordance with principles of inventive concepts, when the memory layer 250 includes transition metal oxide layer, the semiconductor device 2 may be a variable resistance memory device (for example, PRAM).

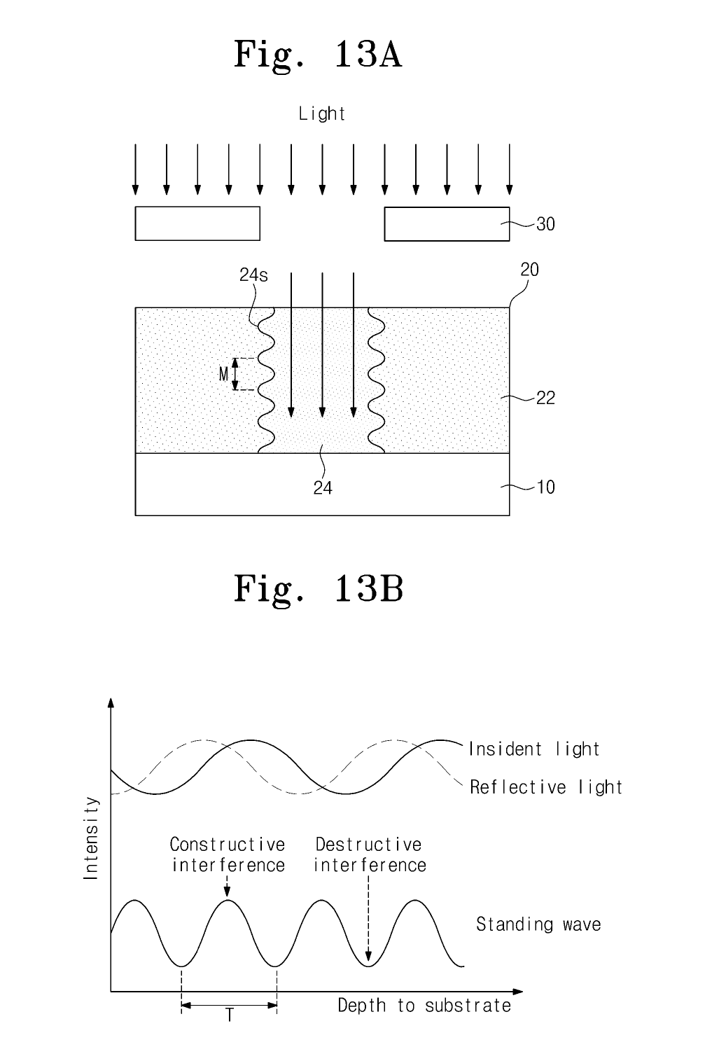

FIG. 13A is a sectional view illustrating a photo process (also referred to herein as a photolithography process) in relation to a patterning method for forming a staircase structure according to an exemplary embodiment in accordance with principles of inventive concepts. FIG. 13B is a graph illustrating a standing wave in relation to a patterning method for forming a staircase structure according to an exemplary embodiment in accordance with principles of inventive concepts.

Referring to FIG. 13A, a photoresist layer 20 may be formed on a processing layer 10 through spin coating and patterned in a desired shape through a photo process, and then the processing film 10 may be patterned in a desired shape through an etching process using the patterned photoresist layer 20. The photoresist layer 20 may include a portion 24 exposed by light that is selectively transmitted through a photo mask 30 and a portion 22 that is not exposed by the light (the term “light” is used herein to refer to electromagnetic radiation of any of a variety of wavelengths that may be employed in photolithography).

Referring to FIG. 13B, light incident upon the photoresist layer 20 may be reflected by the processing layer 10 and incident light and reflected light may superimpose to generate a standing wave whose intensity (or amplitude) changes periodically. For example, the standing wave may have a high intensity due to constructive interference and a low intensity due to destructive interference that appear spatially periodically along a direction perpendicular to the top surface of the substrate, or, of the processing layer. The period T of the standing wave may be proportional to a wavelength of light from the light source irradiating the mask 30 and, through openings in the mask, the photoresist layer 20.

Due to the standing wave effect, the exposed portion 24 may have a side 24s corresponding to a periodic waveform. That is, the photoresist layer 20 may be periodically exposed in a vertical pattern that corresponds to regions receiving overexposure due to light of a high intensity, as a result of constructive interference, and underexposure due to light of a low intensity, as a result of destructive interference. The periodic overexposure and underexposure (that is, spatially periodic) may provide the exposed portion 24 with the waveform side 24s that corresponds to regions of various levels of light intensity and concomitant exposure levels. The unit size M of the wave shape may be proportional to the period T of the standing wave, that is, the wavelength of light used for the exposure.

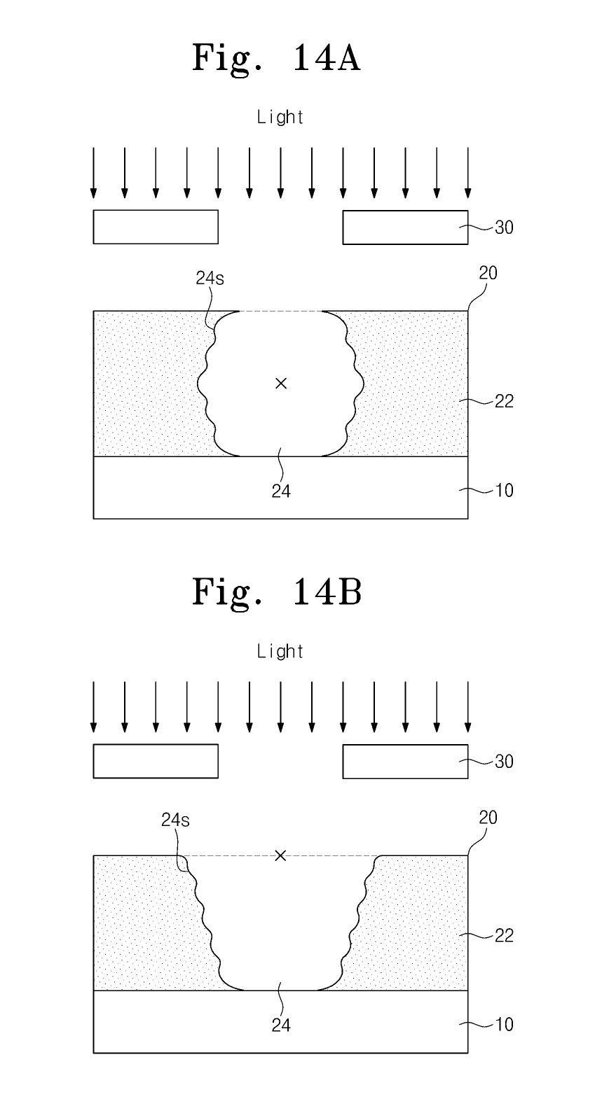

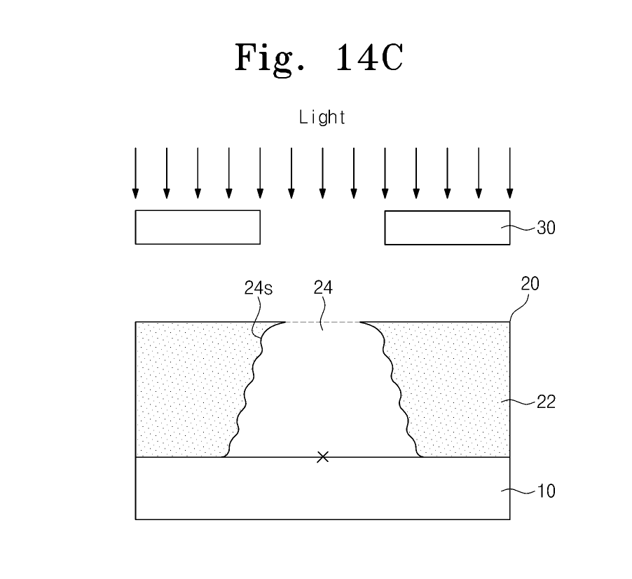

FIGS. 14A to 14C are sectional views illustrating an etching mask in relation to a patterning method for forming a staircase structure according to an exemplary embodiment in accordance with principles of inventive concepts.

Referring to FIGS. 14A to 14C, when the photoresist layer 20 is a positive photoresist, the exposed portion 24 may be removed through a development process so that the unexposed portion 22 may be used as an etching mask. Additionally, the shape of the etching mask may vary according to a focus position of light. In accordance with principles of inventive concepts, the focus position of exposing light may be used in combination with a standing wave to produce a staircase structure, such as that of FIG. 14B, for example. The term “defocusing” may be used herein to refer to focusing light at a preferred depth, in a photoresist layer 20, for example, in order produce an overall shape that may be modified, in detail, by a standing wave effect that may, for example, create a scalloped, or sinusoidal, detail.

As shown in FIG. 14A, when light is focused on a position (indicated with X) corresponding to the middle (of the thickness) of the photoresist layer 20, the side 24s of the exposed portion 24 may be generally vertical convex side, with a scalloped detail due to the standing wave effect. The unexposed portion 22 may have a generally vertical concave side (that is, exhibiting concave openings directed toward one another on either side of the focus position), with a scalloped detail due to the standing wave effect.

In other exemplary embodiments in accordance with principles of inventive concepts, as shown in FIG. 14B, when light is focused on a position corresponding to the top, or its vicinity, of the photoresist layer 20, a larger area of the upper portion of the photoresist layer 20 may be exposed to light than a lower portion (that is, at a lower level) of the photoresist layer 20. As a result, side 24s of the exposed portion 24 may have a staircase shape having a slope inclined upwardly from the processing layer 10 toward the top of the unexposed portion 22. Accordingly, the unexposed portion 22 may have a staircase-shaped side and a lateral width whose value decreases with increasing distance from the processing layer 10.

In other exemplary embodiments in accordance with principles of inventive concepts, as shown in FIG. 14C, when light is focused on a position corresponding to the bottom or its vicinity of the photoresist layer 20, a larger area of the lower portion of the photoresist layer 20 may be exposed to light than at an upper portion of the photoresist layer 20. The side 24s of the exposed portion 24 may have a staircase shape having a slope inclined-upwardly from the processing layer 10 toward the top of the exposed portion 24. Accordingly, the unexposed portion 22 may have a staircase-shaped side and a lateral width whose value increases with increasing distance from the processing layer 10.

As shown in FIGS. 14B and 14C, the unexposed portion 22 having an inclined staircase form, that is, an etching mask, may be formed by performing defocusing exposure and development on the positive photoresist layer 20 in accordance with principles of inventive concepts. That is, in accordance with principles of inventive concepts, the focus position of exposing light may be used in combination with a standing wave to produce a staircase structure, such as that of FIG. 14B or FIG. 14C, for example. And, as previously described, the term “defocusing” may be used herein to refer to focusing light at a preferred depth in a photoresist layer 20, for example, in order produce an overall shape that may be modified, in detail, by a standing wave effect that may, for example, create a scalloped, staircase, or sinusoidal, detail (for example, focused at or near the top of photoresist layer 20 for an outwardly inclined staircase form as in FIG. 14B, or at or near the bottom of photoresist layer 20 for an inwardly inclined staircase form as in FIG. 14C),

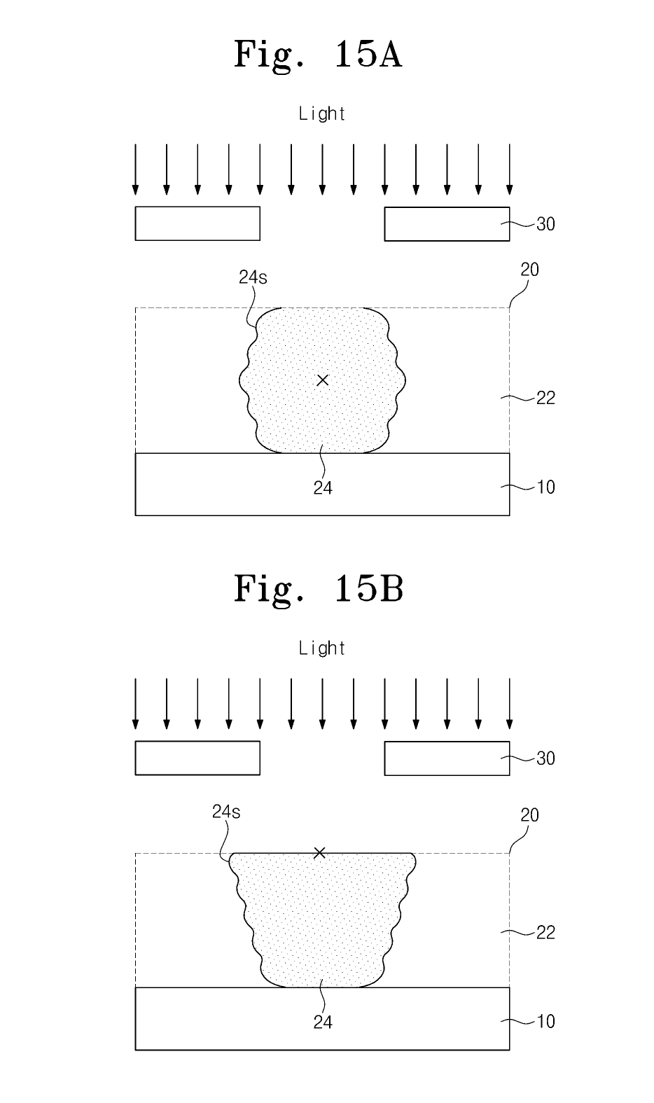

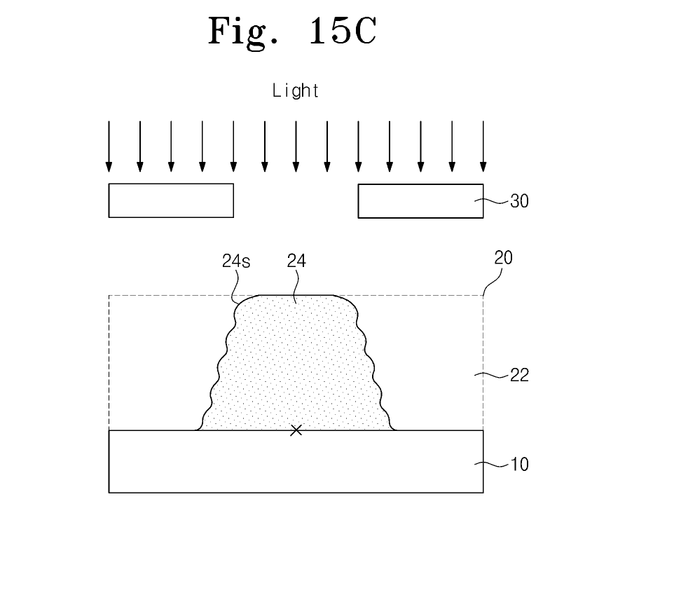

FIGS. 15A to 15C are sectional views illustrating an etching mask in relation to a patterning method for forming a staircase structure according to another exemplary embodiment in accordance with principles of inventive concepts.

Referring to FIGS. 15A to 15C, when the photoresist layer 20 is a negative photoresist, the exposed portion 24 may remain through a development process so that the remaining exposed portion 24 may be used as an etching mask. Additionally, the shape of the etching mask may vary according to a focus position of light and a standing wave effect, in accordance with principles of inventive concepts.

For example, as shown in FIG. 15A, when light is focused on a position (indicated with X) corresponding to a middle thickness of the photoresist layer 20, the side 24s of the exposed portion 24 may have a vertical or convex standing wave shape.

In other exemplary embodiments in accordance with principles of inventive concepts, as shown in FIG. 15B, when light is focused on a position corresponding to a top or its vicinity of the photoresist layer 20, a larger area of the upper portion of the photoresist layer 20 may be exposed to light than at a lower portion of the photoresist layer 20. Accordingly, the exposed portion 24 may have a staircase-shaped side 24s and a lateral width that tapers outwardly with increasing distance from the processing layer 10.

In other exemplary embodiments in accordance with principles of inventive concepts, as shown in FIG. 15C, when light is focused on a position corresponding to the bottom or its vicinity of the photoresist layer 20, a larger area of the bottom portion of the photoresist layer 220 may be exposed to light than at an upper portion of the photoresist layer 20. Accordingly, the exposed portion 24 may have a staircase-shaped side 24s and a lateral width that tapers inwardly with increasing distance from the processing layer 20.

As shown in FIGS. 15B and 15C, the exposed portion 24 having an inclined staircase form, that is, an etching mask, may be formed by performing defocusing exposure and development on the negative photoresist layer 20, for example.

In exemplary embodiments in accordance with principles of inventive concepts, the staircase structure 111 shown in FIG. 3A and the staircase structure 211 shown in FIG. 10B may be formed through the standing wave effect described with reference to FIGS. 13A and 13B, and the defocusing exposure process described with reference to FIG. 14B or FIG. 15C. Hereinafter, a method for forming a staircase structure through the standing wave effect and the defocusing exposure process will be described.

FIGS. 16A and 16F are sectional views corresponding to FIG. 3B and illustrate a method for patterning a staircase structure according to an exemplary embodiment in accordance with principles of inventive concepts.

Referring to FIG. 16A, positive resist such as phenol formaldehyde based polymer may be spin-coated on the mold stack 100 to form a photoresist layer 90. Then, the photoresist layer 90 may be exposed through a defocusing exposure process that places the focus of light (indicated with X) on a position corresponding to a top or its vicinity of the photoresist layer 90 as shown in FIG. 14B. Due to the defocusing exposure, an exposure portion 94 may have a side 94s of a standing wave shape having a slope inclined-upwardly from a bottom of the photoresist layer 90 toward a top of the photoresist layer 90 and a lateral width that tapers inward with increasing distance from the mold stack 100.

In exemplary embodiments in accordance with principles of inventive concepts, in order to obtain a standing wave effect, there may be no need to form an anti-reflective coating (ARC) layer above and/or below the photoresist layer 90. Additionally, in order to maintain the side 94s of the exposed portion 94 as a standing wave, there may be no need to perform a post exposure bake process.

Referring to FIG. 16B, the exposed portion 94 may be selectively removed by providing the defocusing exposed photoresist layer 90 with a developing solution such as Tetramethylammonium hydroxide (TMAH), for example. An unexposed portion 92, that is, an etching mask, may be formed on the mold stack 100 through the development process. The etching mask 92 may have an inclined-upwardly side 92s of a standing wave shape in accordance with principles of inventive concepts.

The height H of the etching mask 92 may vary according to the etching speed of the mold stack 100. For example, when the etching mask 92 has a relatively faster etch rate than the mold stack 100, the etching mask 92 may have the height H greater than that of the mold stack 100.

The etching mask 92 may have the number of unit staircases 93 and the height S of the side 92s that vary according to the height H of the etching mask 92 and a wavelength of light. For example, the number of unit staircases 93 may become less as a wavelength of light may become greater. The number of unit staircases 93 may become greater as the height H of the etching mask 92 may become greater. The height S of the unit staircases 93 may become greater as a wavelength of light may become greater. For example, when defocusing exposure is performed using an I-line exposure source (about 365 nm wavelength) having a shorter wavelength than a G-line exposure source (about 436 nm wavelength), or using an ArF exposure source (about 193 nm wavelength) having a shorter wavelength than a KrF exposure source (about 248 nm wavelength), the height S of the unit staircase 93 may become less and the number of the unit staircase 93 may become greater.

An angle θ of the side 92s of the etching mask 92 with respect to the top surface of the mold stack 100 may become greater as the focus of light (X of FIG. 16A) becomes closer to the mold stack 100. For example, when the focus of light is adjusted to a top of the photoresist layer 90, the angle θ may have a relatively small value, so that the side 92s of the etching mask 92 may have a gentle slope. Alternatively, when the focus of light is adjusted to a bottom of the photoresist layer 90, the angle θ may have a relatively large value, so that the side 92s of the etching mask 92 may have a sharp slope.

Referring to FIGS. 16C to 16F, the staircase structure 111 may be formed by patterning the mold stack 100 through a dry etching process using the etching mask 90. According to exemplary embodiments in accordance with principles of inventive concepts, because the etching mask 92 has the inclined staircase-shaped side 92s, the etching mask 92 may be trimmed repeatedly during the etching process, and simultaneously, the mold insulating layers 120 and the mold sacrificial layers 130 may be patterned. As a result, in accordance with principles of inventive concepts, the staircase structure 111 may be formed through a single etching process without several times of a trimming process on the etching mask 92.

For example, as shown in FIG. 16C, while the etching mask 92 is reduced to an etching mask 92a, a first mold insulating layer 121 and a first mold sacrificial layer 131 may be patterned. In exemplary embodiments in accordance with principles of inventive concepts, the mold insulating layers 120 may include first to fifth mold insulating layers 121 to 125, and the mold sacrificial layers 130 may include first to fourth mold sacrificial layers 131 to 134.

Additionally, as shown in FIG. 16D, while the etching mask 92a is reduced to an etching mask 92b, the first and second mold insulating layers 121 and 122 and the first and second mold sacrificial layers 131 and 132 may be patterned.

And, as shown in FIG. 16E, while the etching mask 92b is reduced to an etching mask 92c, the first to third mold insulating layers 121 to 123 and the first to third mold sacrificial layers 131 to 133 may be patterned.

As shown in FIG. 16F, while the etching mask 92c is etched, the first to fourth mold insulating layers 121 to 124 and the first to fourth mold sacrificial layers 131 to 134 may be patterned. The staircase structure 111 may be formed through such continuous etchings in accordance with principles of inventive concepts.

The staircase process described with reference to FIGS. 16A to 16F may be applied when the gate stack 204 of FIG. 10B is formed as the staircase structure 211.

FIGS. 17A and 17B are sectional views corresponding to FIG. 3B and illustrate a patterning method for forming a staircase structure according to another exemplary embodiment in accordance with principles of inventive concepts.

Referring to FIG. 17A, the photoresist layer 90 may be formed by coating negative resist such as polyisoprene based polymer on the mold stack 100. Then, as shown in FIG. 15C, the photoresist layer 90 may be exposed through a defocusing exposure process that adjusts the focus of light (indicated with X) to a position corresponding to the bottom of the photoresist layer 90, or its vicinity. Due to the defocusing exposure, the exposed portion 94 may have the side 94s of a standing wave shape having a slope inclined upwardly from the bottom of the photoresist layer 90 toward the top of the photoresist layer 90 and having a lateral width that tapers inwardly with increasing distance from the mold stack 100.

Referring to FIG. 17B, the unexposed portion 92 may be selectively removed by providing a developing solution such as Xylene, for example, to the defocusing exposed photoresist layer 90. The exposed portion 94, that is, an etching mask, may be formed on the mold stack 100 through the development process. The etching mask 94 may have the upwardly along the side 94s of a standing wave shape.

In accordance with principles of inventive concepts, through a single etching process using the etching mask 94, as shown in FIG. 16C to 16F, the staircase structure 111 may be formed by patterning the mold stack 100.

The staircase process described with reference to FIGS. 17A and 17B may be applied when the gate stack 204 shown in FIG. 10B is formed to have the staircase structure 211.

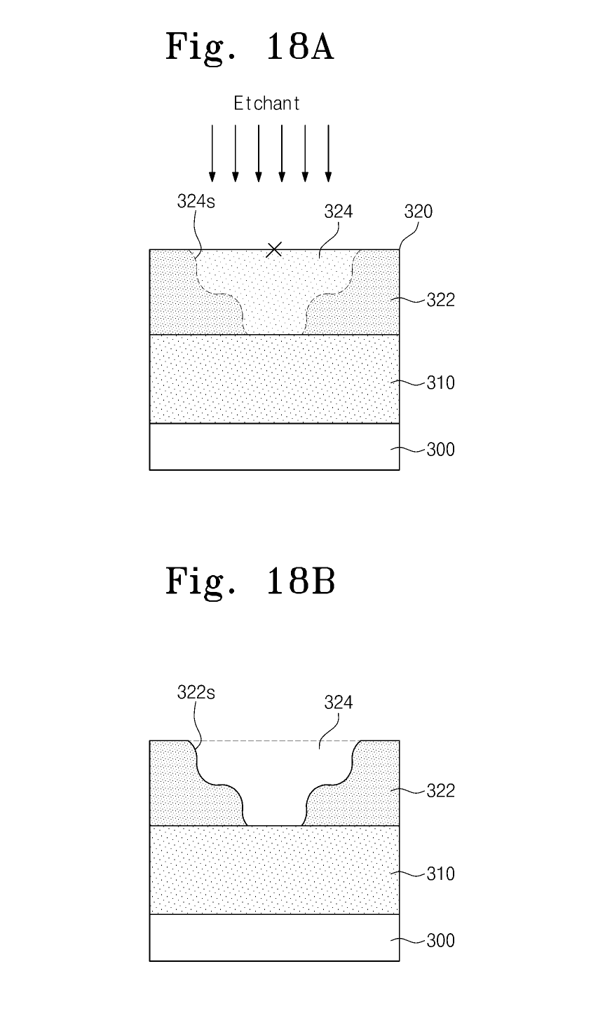

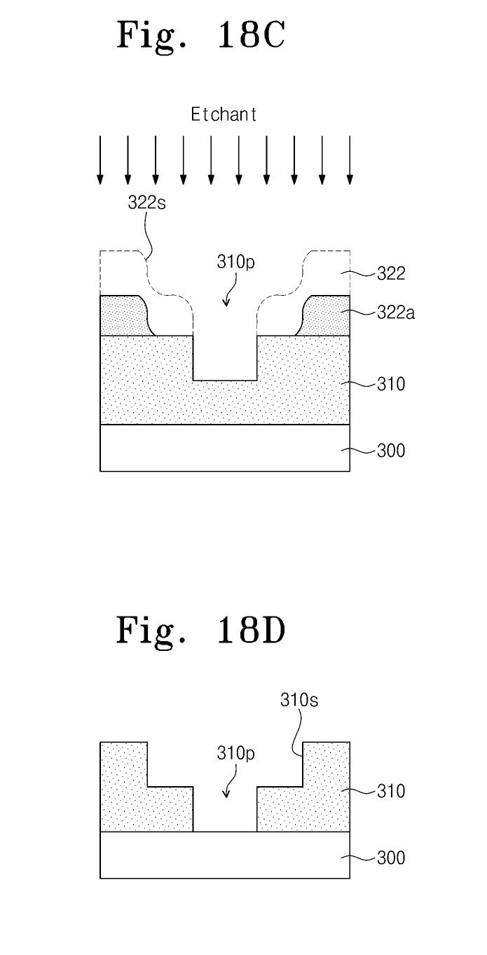

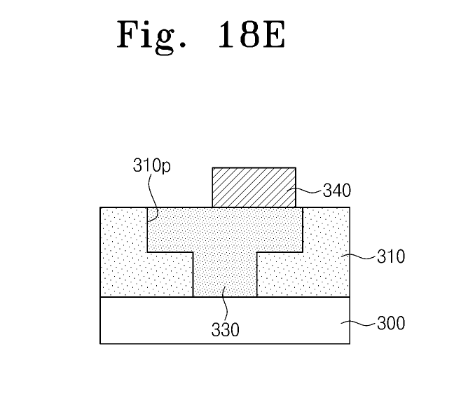

FIGS. 18A to 18E are sectional views illustrating a patterning method for forming a staircase structure according to another exemplary embodiment in accordance with principles of inventive concepts.

Referring to FIG. 18A, in accordance with principles of inventive concepts, a photoresist layer 320 may be formed on a processing layer 310 disposed on a substrate 300, and the photoresist layer 320 may be exposed. The substrate 300 may be a semiconductor substrate such as a silicon wafer, and the processing layer 310 may be a single insulating layer such as silicon oxide layer or a silicon nitride layer, or may be a multiple insulating layer such as a silicon oxide layer and a silicon nitride layer that are vertically stacked. The photoresist layer 320 may be foil led by spin-coating positive resist. As described with FIG. 14B, the photoresist layer 320 may be exposed through a defocusing exposure process that adjusts the focus of light to a position corresponding to the top of the photoresist layer 320 or its vicinity. Due to the defocusing exposure, an exposed portion 324 may have a lateral width that tapers outwardly with increasing distance from the processing layer 310 and an inclined upwardly along the side 324s of a standing wave shape.

Referring to FIG. 18B, the exposed portion 324 may be selectively removed through a development process. As a result, an unexposed portion 322 using as an etching mask may remain on the processing layer 310. The etching mask 322 may have an inclined upwardly along the side 322s of a standing wave shape.

Referring to FIG. 18C, the processing layer 310 may be patterned through an etching process using the etching mask 322. As a result, a recess pattern 310p may be formed by removing a portion of the processing layer 310. While the etching mask 322 is reduced to an etching mask layer 322a, the processing layer 310 may be continuously patterned.

FIG. 18D illustrates a side of the recess pattern 310p which may have a staircase structure through continuous etching. In exemplary embodiments in accordance with principles of inventive concepts, since the etching mask 322 has an inclined staircase-shaped side 322s, the recess pattern 310p may be formed to have both narrow width and wide width through a single etching process. The recess pattern 310p may have a hole or line shape depending on the shape of the exposed portion 324.

Referring to FIG. 18E, the recessed pattern 310p may be filled with conductor to form a metal contact 330 electrically connected to the substrate 300. Since the metal contact 330 has a top portion wider than a bottom portion, contact between the metal contact 330 and a misaligned metal wire 340 may be improved or contact resistance may be reduced in accordance with principles of inventive concepts.

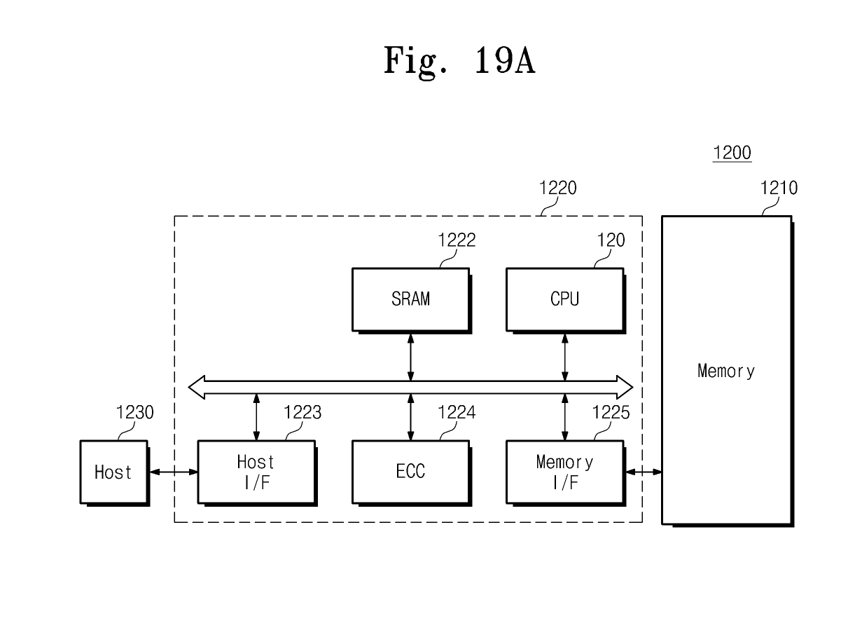

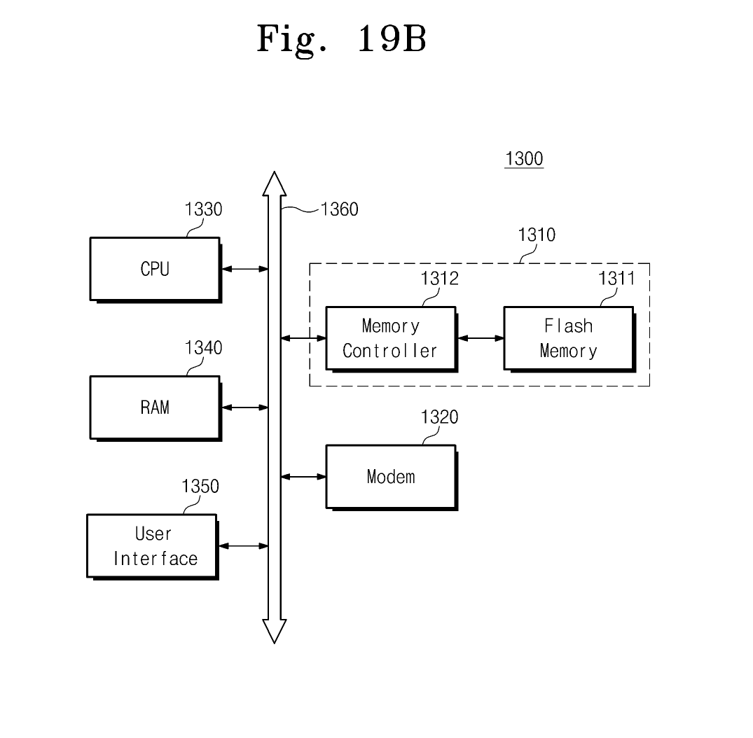

FIG. 19A is a block diagram illustrating a memory card including a semiconductor device according to embodiments of the present invention. FIG. 19B is a block diagram illustrating an information processing system including a semiconductor device applied according to embodiments of the present invention.

Referring to FIG. 19A, a memory 1210 including at least one of the semiconductor devices 1, 1a, 1b, and 2 according to exemplary embodiments in accordance with principles of inventive concepts may be applied to the memory card 1200. For example, the memory card 1200 may be included in a memory controller 1220 controlling general data exchange between a host 1230 and the memory 1210. An SRAM 1222 may operate as an operating memory of a central processing unit (CPU) 1220. A host interface 1223 may include a data exchange protocol between the memory card 1200 and the accessing host 1230. An error correction code 1224 may detect and correct an error in data read from the memory 1210. A memory interface 1225 may interface with the memory 1210. The CPU 1220 may perform a general control operation for data exchange of the memory controller 1220.

Referring to FIG. 19B, information processing system 1300 may include a memory system 1310 including at least one of the exemplary embodiments of semiconductor devices 1, 1a, 1b, and 2 according to principles of inventive concepts. The information processing system 1300 may include a mobile device or a computer. For example, the information processing system 1300 may include a modem 1320, a CPU 1330, a RAM 1340, and a user interface 1350, which are connected to the memory system 1310 via a system bus 1360. The memory system 1310 includes a memory 1311 and a memory controller 1312, and may be substantially identical to the memory card 1200 of FIG. 19A. The memory system 1310 may store data processed by the CPU 1330 or data inputted from the outside. The information processing system 1300 may include a memory card, a solid state disk (SSD), a camera image sensor, and other application chipsets. For example, the memory system 1300 may be configured with an SSD. In this case, the information processing system 1300 may store large amounts of data in the memory system 1310 stably and reliably.

In accordance with principles of inventive concepts, a staircase structure may be formed using a single etching process, thereby reducing manufacturing costs and improving yield. Furthermore, process defects are reduced, so that a semiconductor device having improved characters may be realized.

The above-disclosed subject matter is to be considered illustrative and not restrictive. The scope of inventive concepts is to be determined by the broadest permissible interpretation of the following claims and their equivalents, and shall not be restricted or limited by the foregoing detailed description.

What is claimed is:

1. A patterning method comprising:
forming a photoresist layer on a processing layer;
performing defocusing and standing-wave exposure on the photoresist layer;
developing the defocusing exposed photoresist layer to an etching mask having a side of a staircase shape; and
patterning the processing layer by an etching process using the etching mask to change the processing layer into a staircase structure.

2. The method of claim 1, wherein the performing of the defocusing exposure on the photoresist layer comprises performing the defocusing exposure by adjusting a focus of light to a level higher or lower than a middle height of the photoresist layer.

3. The method of claim 2, wherein the photoresist layer comprises positive resist, and the performing of the defocusing exposure on the photoresist layer comprises performing the defocusing exposure by adjusting a focus of light to a level higher than a middle height of the positive resist.

4. The method of claim 3, wherein the forming of the etching mask comprises providing the positive resist with a developing solution to selectively remove an exposed portion of the positive resist,
wherein an unexposed portion of the positive resist is used as the etching mask, the unexposed portion of the positive resist upwardly inclined along the side of the staircase shape and a width that tapers inward with increasing distance from the processing layer.

5. The method of claim 2, wherein the photoresist layer comprises negative resist, wherein the performing of the defocusing exposure on the photoresist layer comprises performing the defocusing exposure by adjusting a focus of light to a level lower than a middle height of the negative resist.

6. The method of claim 5, wherein the forming of the etching mask comprises providing the negative resist with a developing solution to selectively remove an unexposed portion of the negative resist,
wherein an exposed portion of the negative resist is used as the etching mask, the exposed portion of the negative resist upwardly inclined along the side of the staircase shape and a width that tapers inward with increasing distance from the processing layer.

7. The method of claim 1, wherein the forming of the photoresist layer comprises coating positive resist or negative resist on the processing layer without forming an anti-reflective layer on at least one of the processing layer and the photoresist layer.

8. The method of claim 1, wherein the performing of the defocusing exposure on the photoresist layer comprises performing exposure by adjusting a focus of light to a top surface or a bottom surface of the photoresist layer without performing post exposure bake on the photoresist layer.

9. The method of claim 1, wherein the processing layer comprises a single layer or a multiple layer.

10. The method of claim 1, wherein the changing of the processing layer into the staircase structure comprises changing the processing layer into a pyramid structure including an outer lateral side having the staircase shape and a width that tapers inward with increasing distance from the processing layer.

11. The method of claim 1, wherein the changing of the processing layer into the staircase structure comprises changing the processing layer into a recessed structure including an inner surface having the staircase shape and a width that tapers outward with increasing distance from the processing layer.

12. A method for fabricating a semiconductor device, the method comprising:
forming a multiple layer including different material layers vertically stacked alternatingly along a vertical channel standing on a substrate;
forming an etching mask having an inclined side of a staircase shape on the multiple layer; and
patterning the multiple layer by an etching process using the etching mask to form a side of the multilayer with a staircase structure,
wherein the forming of the etching mask comprises:
forming a photoresist layer on the multiple layer;
performing defocusing and standing wave exposure on the photoresist layer by adjusting a focus of a light to a level higher or lower than a middle height of the photoresist layer; and
developing the defocusing exposed photoresist layer.

13. The method of claim 12, wherein the multilayer comprises a mold stack including insulating layers and sacrificial layers that are vertically stacked alternatingly on the substrate,
wherein the mold stack is patterned through the etching process to have the staircase structure in which adjacent insulating and conductive layers are not covered by directly above adjacent insulating and conductive layers.

14. The method of claim 13, after the forming of the side of the multiple layer with the staircase structure, further comprising:
selectively removing the sacrificial layers to form recess regions between the insulating layers; and
filling the recess regions with conductive layers to form a plurality of gates stacked along the vertical channel, each gate having a pad not covered by a directly above adjacent conductive layer.

15. The method of claim 12, wherein the multiple layer comprises a gate stack including insulating layers and conductive layers vertically stacked alternatingly on the substrate,
wherein the gate stack is patterned through the etching process to have the staircase structure in which adjacent insulating and conductive layers are not covered by directly above adjacent insulating and conductive layers.

16. A method, comprising: forming a photoresist layer on a processing layer;
performing standing-wave exposure on the photoresist layer;
focusing the standing wave exposure at a level other than at the center of the photoresist layer;
developing the exposed photoresist layer to form an etching mask having a staircase shaped side; and
patterning the processing layer by an etching process using the etching mask to form a staircase-structured processing layer.

17. The method of claim 16, wherein standing wave exposure includes reflecting light off a surface below the photoresist layer to constructively and destructively interfere and to thereby expose areas of the photoresist to different degrees.

18. The method of claim 17, wherein the exposure is focused at or near the bottom of the photoresist layer to form a region of exposed photoresist in a staircase pattern that inclines outwardly toward the top of the photoresist layer.

19. The method of claim 17, wherein the exposure is focused at or near the top of the photoresist layer to form a region of exposed photoresist in a staircase pattern that inclines inwardly toward the top of the photoresist layer.

20. The method of claim 16, wherein the unexposed portion of the resist is used as an etch mask.
